(19) United States
(12) Patent Application Publication
(10) Pub. No.: US 2006/0163744 A1
(43) Pub. Date: Jul. 27, 2006

(54) Printable electrical conductors

(75) Inventors: Karel Vanheusden, Placitas, NM (US); Klaus Kunze, Albuquerque, NM (US); Hyungrak Kim, Albuquerque, NM (US); Aaron D. Stump, Albuquerque, NM (US); Allen B. Schult, Albuquerque, NM (US); Mark J. Hampden-Smith, Albuquerque, NM (US); Chuck Edwards, Rio Rancho, NM (US); Anthony R. James, Rio Rancho, NM (US); James Caruso, Albuquerque, NM (US); Toivo T. Kodas, Albuquerque, NM (US); Scott Thomas Haubrich, Albuquerque, NM (US); Mark H. Kowalski, Albuquerque, NM (US)

Correspondence Address: Jaimes Sher, Esq.;Cabot Corporation, 5401 Venice Avenue NE, Albuquerque, NM, 87113, US

(73) Assignee: Cabot Corporation, Boston, MA (US)

(21) Appl. No.: 11/331,231

(22) Filed: Jan. 13, 2006

Related U.S. Application Data
(60) Provisional application No. 60/643,577, filed on Jan. 14, 2005.
(60) Provisional application No. 60/643,629, filed on Jan. 14, 2005.
(60) Provisional application No. 60/643,578, filed on Jan. 14, 2005.
(60) Provisional application No. 60/695,405, filed on Jul. 1, 2005.

(51) Int. Cl. H01L 23/48

(52) U.S. Cl. 257/773

(57) ABSTRACT

An electrical conductor formed from one or more metallic inks. The electrical conductor comprises a network of interconnected metallic nodes. Each node comprises a metallic composition, e.g., one or more metals or alloys. The network defines a plurality of pores having an average pore volume of less than about 10,000,000 nm³. The electrical conductors advantageously have a high degree of conductivity, e.g., a resistivity of not greater than about 10× the resistivity of the (bulk) metallic composition, which forms the individual nodes.

### CROSS REFERENCE TO RELATED APPLICATIONS

This application claims priority to U.S. Provisional Patent Application Ser. Nos. 60/643,577; 60/643,629; and 60/643,378, all filed on Jan. 14, 2005, and to U.S. Provisional Patent Application No. 60/695,405, filed on Jul. 1, 2005, the entireties of which are incorporated herein by reference.

### FIELD OF THE INVENTION

The present invention relates to electrical conductors. More particularly, the invention relates to electrical conductors that may be formed by depositing a metallic ink on a substrate through a direct write deposition process, and processing the deposited ink at low temperatures to form the electrical conductor.

### BACKGROUND OF THE INVENTION

The electronics, display and energy industries rely on the formation of coatings and patterns of conductive materials to form circuits on organic and inorganic substrates. The primary methods for generating these patterns include screen printing for features larger than about 100 μm and thin film and etching methods for features smaller than about 100 μm. Other subtractive methods to attain fine feature sizes include the use of photo-patternable pastes and laser trimming.

One consideration with respect to patterning of conductors is cost. Non-vacuum, additive methods generally entail lower costs than vacuum and subtractive approaches. Some of these printing approaches utilize high viscosity flowable liquids. Screen-printing, for example, uses flowable mediums with viscosities of thousands of centipoise. At the other extreme, low viscosity compositions can be deposited by methods such as ink-jet printing. However, low viscosity compositions are not as well developed as the high viscosity compositions.

Ink-jet printing of conductors has been explored, but most approaches to date have been inadequate for producing well-defined features with good electrical properties, particularly at relatively low temperatures.

There exists a need for compositions for fabricating electrical conductors for use in electronics, displays, and other applications. Further, there is a need for compositions that have low processing temperatures to allow deposition onto organic substrates and subsequent thermal treatment. It would also be advantageous if the compositions could be deposited with a fine feature size, such as not greater than about 100 μm, while still providing electronic features with adequate electrical and mechanical properties.

An advantageous metallic ink and its associated deposition technique for the fabrication of electrical conductors should combine a number of attributes. The metallic ink should be able to form an electrical conductor having a high conductivity, preferably close to that of the pure bulk metal. The processing temperature should be low enough to allow formation of conductors on a variety of organic substrates (polymers). The deposition technique should allow deposition onto surfaces that are non-planar (e.g., not flat). The ink should form conductors having good adhesion to the substrate. The composition would desirably be inkjet printable, allowing the introduction of cost-effective material deposition for production of devices such as flat panel displays (PDP, AMLCD, OLED). The composition would desirably also be flexo, gravure, or offset printable, again enabling lower cost and higher yield production processes as compared to screen printing.

Further, there is a need for electronic circuit elements, particularly electrical conductors, and complete electronic circuits fabricated on inexpensive, thin and/or flexible substrates, such as paper, using high volume printing techniques such as reel-to-reel printing. Recent developments in organic thin film transistor (TFT) technology and organic light emitting device (OLED) technology have accelerated the need for complimentary circuit elements that can be written directly onto low cost substrates. Such elements include conductive interconnects, electrodes, conductive contacts and via fills.

### SUMMARY OF THE INVENTION

In one embodiment, the present invention is directed to a printable electrical conductor, comprising a network of interconnected metallic nodes, the nodes comprising a metallic composition, the network defining a plurality of pores having an average pore volume of less than about 10,000,000 nm³, e.g., less than about 1,000,000 nm³, less than about 100,000 nm³, less than about 50,000 nm³ or less than about 20,000 nm³, and the electrical conductor having a resistivity of not greater than about 15×, e.g., not greater than about 10× or not greater than about 5×, the resistivity of the bulk metallic composition that forms the nodes. In a preferred embodiment, the network comprises fused interconnected metallic nodes.

The metallic composition optionally comprises a metal selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead. Additionally or alternatively, the metallic composition comprises an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead. The alloy optionally comprises a combination of metals selected from the group consisting of silver/nickel, silver/copper, silver/cobalt, platinum/copper, platinum/ruthenium, platinum/iridium, platinum/gold, palladium/gold, palladium/silver, nickel/copper, nickel/chromium, and titanium/palladium/gold. In another aspect, the alloy comprises at least three metals.

In one embodiment, at least a portion of the pores are at least partially filled with a composition selected from the group consisting of carbon, alumina, silica, and glass. In another aspect, at least a portion of the pores are at least partially filled with an organic material. The organic material may comprise one or more remaining ink solvent. Additionally or alternatively, the organic material may comprise an organic polymer, which optionally comprises units of a monomer, which optionally comprises at least one heteroatom selected from O and N. Additionally or alternatively, the polymer comprises units of a monomer which comprises one or more of a hydroxyl group, a carbonyl group, an ether group, an amido group, a carboxyl group, an imido group and/or an amino group. Additionally or alternatively, the polymer comprises units of at least one monomer which comprises a structural element selected from —COO—, —O—CO—O—, —C—O—C—, —CO—O—CO, —CONR—, —NR—CO—O—, —NR¹—CO—NR²—, —CO—NR—CO—, —SO₂—NR— and —SO₂—O—, wherein R, R¹ and R² independently represent hydrogen or an organic radical. In a preferred embodiment, the polymer comprises a polymer of vinylpyrrolidone, e.g., a homopolymer or a copolymer. The copolymer may be selected from the group consisting of a copolymer of vinylpyrrolidone and vinylacetate; a copolymer of vinylpyrrolidone and vinylimidazole; a copolymer of vinylpyrrolidone and styrene; a copolymer of vinylpyrrolidone and 2-dimethylaminoethyl methacrylate; and a copolymer of vinylpyrrolidone and vinylcaprolactam.

The electrical conductor optionally comprises the pores in an amount less than about 50 volume percent, e.g., less than about 25 volume percent, based on the total volume of the electrical conductor. The average distance between adjacent pores optionally is from about 1 nm to about 500 nm. The pores may have an ordered or disordered (random) arrangement within the electrical conductor.

The electrical conductor of the present invention may be formed by a process comprising the steps of: (a) providing an ink comprising metallic nanoparticles and a liquid vehicle; (b) depositing the ink on a substrate; and (c) removing a majority of the liquid vehicle from the deposited ink to form the nodes and the pores in the electrical conductor. Step (c) optionally comprises heating the deposited ink under conditions effective to remove the majority of the liquid vehicle, and sinter adjacent metallic nanoparticles to one another to form the nodes and the pores of the electrical conductor. Step (c) may comprise heating the ink on the substrate to a maximum temperature of less than about 200° C., e.g., less than about 100° C.

The ink optionally further comprises a composition selected from the group consisting of alumina, silica, glass, and carbon, the composition filling at least a portion of the pores in step (c). Additionally or alternatively, the ink further comprises an organic material (as discussed above), which fills at least a portion of the pores in step (c).

In another embodiment, the invention is to an electrical conductor, comprising a plurality of touching (but substantially unsintered) metallic nanoparticles, wherein the nanoparticles are tightly packed and form a plurality of voids, wherein at least about 95 percent, e.g., at least about 99 percent, of the nanoparticles, by number, are not sintered to any adjacent nanoparticles, the electrical conductor having a resistivity of not greater than about 20×, e.g., not greater than about 10× or not greater than about 5×, the resistivity of the bulk metallic composition forming the nanoparticles. The average void volume optionally is less than about 10,000,000 nm³, e.g., less than about 1,000,000 nm³, less than about 100,000 nm³, less than about 50,000 nm³, or less than about 20,000 nm³.

The metallic nanoparticles optionally comprise a metal selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead. Additionally or alternatively, the metallic nanoparticles comprise an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead. Additionally or alternatively, the alloy comprises a combination of metals selected from the group consisting of silver/nickel, silver/copper, silver/cobalt, platinum/copper, platinum/ruthenium, platinum/iridium, platinum/gold, palladium/gold, palladium/silver, nickel/copper, nickel/chromium, and titanium/palladium/gold. In one aspect, the alloy comprises at least three metals.

In one aspect, at least a portion of the voids are at least partially filled with a composition selected from the group consisting of carbon, alumina, silica, and glass. Additionally or alternatively, at least a portion of the voids are at least partially filled with an organic material (as discussed above). The organic material may fill at least 70 volume percent, at least 90 volume percent, or at least 95 volume percent of the voids.

### BRIEF DESCRIPTION OF THE DRAWINGS

The present invention will be better understood in view of the following non-limiting figures, wherein:

FIG. 1 illustrates a metallic ink deposited on a substrate;

FIG. 2 illustrates metallic nanoparticles disposed on a substrate prior to heating or curing;

FIG. 3 illustrates an electrical conductor according to one embodiment of the present invention;

FIG. 4 illustrates an electrical conductor according to another embodiment of the present invention;

FIG. 5 is a scanning electron micrograph (SEM) showing a top-view of a printed electrical conductor according to one embodiment of the present invention;

FIG. 6 is a SEM showing a cross-section of a printed electrical conductor according to one embodiment of the present invention;

FIG. 7 is a SEM showing a printed electrical conductor according to one embodiment of the present invention; and

FIG. 8 is a SEM of the printed electrical conductor shown in FIG. 7 under increased magnification.

### DETAILED DESCRIPTION OF THE INVENTION

I. Introduction

In one aspect, the present invention is directed to an electrical conductor, which comprises a network of interconnected metallic nodes. Each node comprises a metallic composition, e.g., one or more metals or alloys. The network defines a plurality of pores having an average pore volume of less than about 10,000,000 nm³. The electrical conductors advantageously have a high degree of conductivity, which may be expressed by comparison to the resistivity of the bulk metallic composition that forms the individual nodes. For example, the electrical conductor, in a preferred aspect, has a resistivity of not greater than about 10× the resistivity of the (bulk) metallic composition.

In a preferred aspect of the invention, the electrical conductor is formed by a process comprising the steps of: (a) providing an ink comprising metallic nanoparticles and a liquid vehicle; (b) depositing the ink on a substrate; and (c) removing a majority of the liquid vehicle from the deposited ink to form the nodes and the pores in the electrical conductor. In one aspect, step (c) comprises heating the deposited ink under conditions effective to remove a majority of the liquid vehicle, and sinter adjacent metallic nanoparticles to one another to form the nodes and the pores of the electrical conductor.

In another aspect, the invention is to an electrical conductor, comprising a plurality of touching (but substantially unsintered) metallic nanoparticles, wherein the nanoparticles are tightly packed and form a plurality of voids, wherein at least about 95 percent, e.g., at least about 99 percent, of the nanoparticles, by number, are not sintered to any adjacent nanoparticles, the electrical conductor having a resistivity of not greater than about 20×, e.g., not greater than about 10× or not greater than about 5×, the resistivity of the bulk metallic composition forming the nanoparticles. The average void volume optionally is less than about 10,000,000 nm³, e.g., less than about 1,000,000 nm³, less than about 100,000 nm³, less than about 50,000 nm³, or less than about 20,000 nm³.

II. Electrical Conductors

Thus, in one aspect, the present invention is directed to an electrical conductor, which comprises a network of interconnected metallic nodes. Preferably, the network comprises fused interconnected metallic nodes. Each node comprises a metallic composition, e.g., one or more metals or alloys. The network defines a plurality of pores having an average pore volume of less than about 10,000,000 nm³.

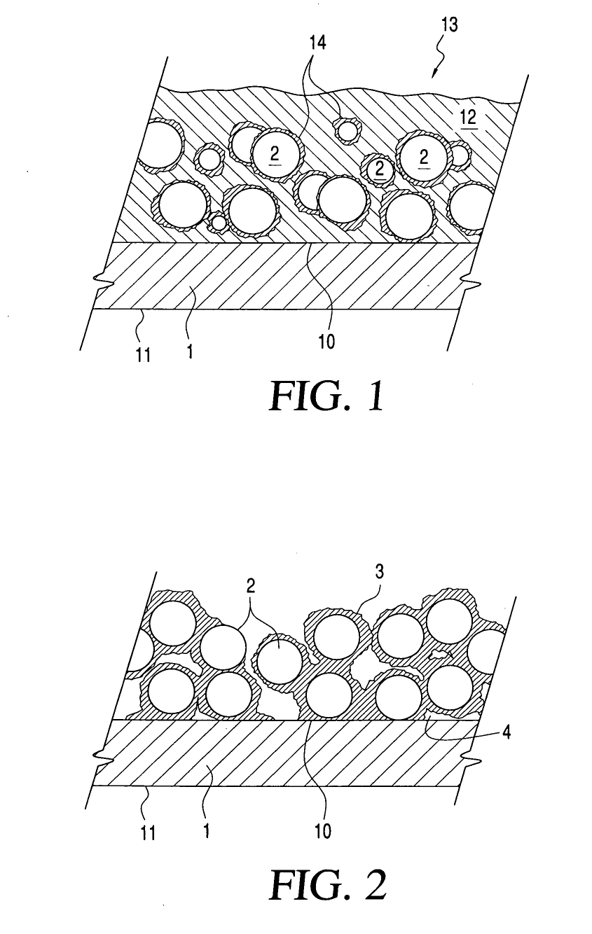

As used herein, the term “node” means a localized region (on the nanoparticle scale) of high metallic phase concentration, wherein the region is formed from a single metallic nanoparticle. FIGS. 1-4, which are not drawn to scale, conceptually illustrate how nodes are formed from metallic nanoparticles in a metallic ink. FIG. 1 illustrates a substrate 1 having opposing major planar surfaces 10 and 11, and a metallic ink, generally designated 13, deposited on surface 10 of substrate 1. The metallic ink 13 comprises a liquid vehicle 12 and a plurality of metallic nanoparticles 2 dispersed in the liquid vehicle 12. As shown, each nanoparticle 2 includes a metallic core and a capping agent 14, e.g., polyvinylpyrrolidone, disposed on at least a portion of the surface of the metallic core. The capping agent 14 preferably inhibits agglomeration of the nanoparticles 2 while in ink form.

As indicated above, after deposition of the metallic ink 13, the liquid vehicle preferably is removed from the deposited ink. FIG. 2 illustrates the metallic ink from FIG. 1, after removal of a majority of the liquid vehicle, but prior to heating and/or curing to form the electronic feature of the present invention. As shown, a plurality of metallic nanoparticles 2, derived from a metallic ink, are shown disposed on surface 10 of substrate 1. In the embodiment shown in FIG. 2, a capping agent 3, e.g., polyvinylpyrrolidone, is shown disposed on and substantially surrounding the nanoparticles 2. Optionally, the capping agent 3 is chemically bonded to the surfaces of the nanoparticles 2. The degree to which the capping agent surrounds the nanoparticles 2 will particularly depend on the amount of capping agent 3 present in the ink relative to the amount of the metallic nanoparticles 2 present in the ink. In other aspects, not shown, one or more binding agents, adhesion agents and/or fusing agents may be disposed on and/or around the metallic nanoparticles 2 much in the same manner as the capping agent 3 surrounds the nanoparticles 2.

The majority of the metallic nanoparticles 2 shown in FIG. 2 are not in a touching relationship with adjacent nanoparticles, although some (a minority of) adjacent nanoparticles are in a touching relationship with one another. Accordingly, the conductivity of the feature shown in FIG. 2 would be poor. The degree to which adjacent nanoparticles are touching one another will depend, inter alia, on multiple factors such as the concentration of the metallic nanoparticles 2 in the ink, and the processing conditions (e.g., temperature and time exposed to elevated temperature) used to form the desired electronic feature.

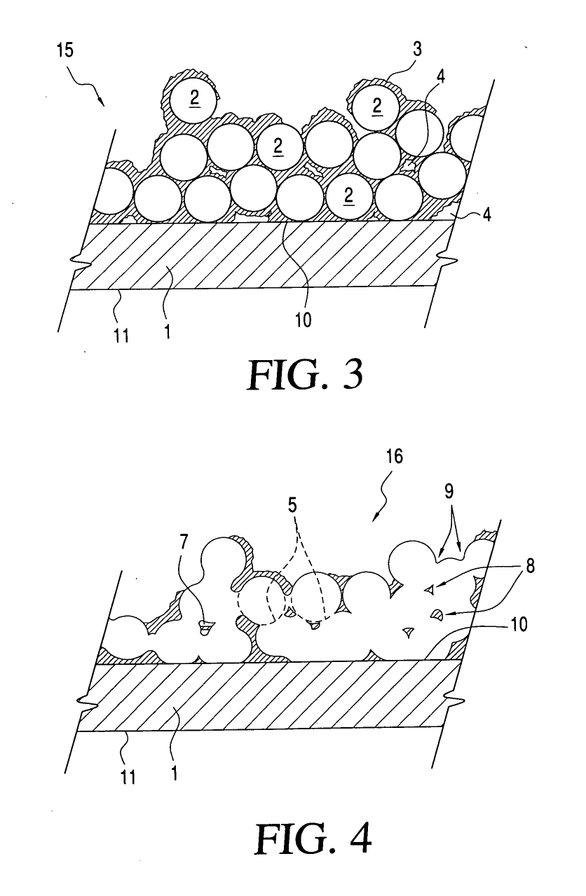

In order to have high conductivity, it is desired that a majority of the metallic nanoparticles be in a touching relationship (optionally sintered) with adjacent nanoparticles. In a preferred aspect of the present invention, the ink is heated and the capping agent 3 moves out of the way as the ink is heated, allowing the nanoparticles 2 to move closer to each other. As shown in FIG. 3, as the capping agent moves out of the way, a majority of the metallic nanoparticles 2 are moved into a touching relationship with at least one adjacent nanoparticle. At this stage, the feature has a relatively high conductivity that may be acceptable for the desired application.

Thus, FIG. 3 illustrates a first embodiment of the present invention. Specifically, FIG. 3 shows an electrical conductor, generally designated 15, comprising a plurality of touching (but substantially unsintered) metallic nanoparticles 2, wherein the nanoparticles 2 are tightly packed and form a plurality of voids 4, wherein at least about 95 percent of the nanoparticles 2, by number, are not sintered to any adjacent nanoparticles, the electrical conductor 15 having a resistivity of not greater than about 20×, e.g., not greater than about 10× or not greater than about 5×, the resistivity of the bulk metallic composition. The average void volume optionally is less than about 10,000,000 nm³, e.g., less than about 1,000,000 nm³, less than about 100,000 nm³, less than about 50,000 nm³, or less than about 20,000 nm³. In terms of ranges, the void volume optionally ranges from about 100,000 nm³ to about 10,000,000 nm³, e.g., from about 750,000 nm³ to about from about 4,000,000 nm³, or from about 1,000,000 nm³ to about 3,000,000 nm³.

The metallic nanoparticles 2 optionally comprise a metal selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead. Additionally or alternatively, the metallic nanoparticles 2 comprise an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead. Additionally or alternatively, the alloy comprises a combination of metals selected from the group consisting of silver/nickel, silver/copper, silver/cobalt, platinum/copper, platinum/ruthenium, platinum/iridium, platinum/gold, palladium/gold, palladium/silver, nickel/copper, nickel/chromium, and titanium/palladium/gold. In one aspect, the alloy comprises at least three metals.

In one aspect, at least a portion of the voids 4 are at least partially filled with a composition selected from the group consisting of carbon, alumina, silica, and glass. Additionally or alternatively, at least a portion of the voids 4 are at least partially filled with an organic material, e.g., PVP, glycerol, ethylene glycol or a reaction product thereof. The organic material may fill at least 70 volume percent, at least 90 volume percent, or at least 95 volume percent of the voids.

If further conductivity is desired, the feature shown in FIG. 3 may be further heated (for a longer period of time and/or at a higher temperature) under conditions effective to cause at least a majority of the touching nanoparticles 3 to sinter to at least one adjacent nanoparticle. As the nanoparticles fuse or sinter to one another, a percolation network of nodes (after sintering) is created, forming a final electrical conductor according to another embodiment of the present invention, as shown in FIG. 4. This feature has very high conductivity, approaching that of the bulk metallic material.

An exemplary electrical conductor according to this aspect of the present invention is illustrated in FIG. 4. As discussed in more detail below, the processes for forming the electrical conductors of the present invention preferably include a step of heating and/or curing a deposited metallic ink under conditions effective to cause at least some, preferably a majority, of adjacent nanoparticles to connect or fuse to one another. More specifically, after heating and/or curing, adjacent nanoparticles 2 shown, for example, in FIG. 3 connect or fuse to one another to form a network of interconnected nodes 5, each of which is derived from a respective metallic nanoparticle 2. Although FIGS. 2-4 illustrate, for simplicity, a two-dimensional network of nanoparticles 2 (nodes 5 separated by necking regions 9 in FIG. 4), one skilled in the art should appreciate that the nanoparticles 2 (in FIGS. 1-3) and the network of nodes 5, necking regions 9 and pores 8 shown in FIG. 4 will typically be formed in a three-dimensional arrangement, that is, in the x, y and z directions.

The regions that connect adjacent nanoparticles are referred to herein as necking regions 9. By connecting adjacent nanoparticles to one another to form a network of interconnected nodes, a continuous percolation network may be formed that provides continuous channels for the conduction of electrons throughout the printed structure without obstacles. As a result, the electrical conductor of this aspect of the present invention possesses surprisingly high conductivity.

It is contemplated that the volume of a respective node 5 may be smaller than the volume of the metallic nanoparticle from which it was formed due to the rearrangement of the metallic material in the nanoparticle to form at least a portion of the adjacent necking region(s) 9 in addition to the node 5. In some embodiments, a fusing agent, if included in the ink, may form all or a portion of the necking region 9.

In the embodiment shown in FIG. 4, a plurality of pores 8 are formed by the network of nodes as adjacent nanoparticles 2 are connected to one another. Depending on the particular ink compositions used to form the electrical conductor, the pores 8 may or may not be filled with a component derived from the ink. In a preferred embodiment, shown in FIG. 4, at least a portion of the pores 8 are filled, at least partially, with the capping agent 3. For example, a PVP capping agent that was bound to a metallic, e.g., Ag, nanoparticle surface may be removed from the surface during curing and could fill the pores of the metallic network. Advantageously, in some aspects of the invention, the presence of the capping agent 3 in the pores 8 may improve the conductivity of the resulting electrical conductor. Additionally or alternatively, all or a portion of the pores may be filled, at least partially with a gaseous composition, e.g., air, as shown by gaseous volume 7. In various other embodiments, the pores 8 may be filled with one or more of air, nitrogen, argon, adhesion agents, a fusing agent, and/or capping agents. Additionally or alternatively, the pores may be filled, at least partially, with one or more organic materials other than PVP, such as but not limited to, glycerol, ethylene glycol or reaction products thereof.

The conductors according to the present invention may have combinations of various characteristics. The electrical conductor preferably has a high (although not necessarily total) purity, a high electrical conductivity and/or high electromigration resistance. In one aspect, the electrical conductor is substantially or totally free of adulterants that reduce conductivity. High conductivity can, for example, be provided by forming the electrical conductor from inks comprising nanoparticles of, e.g., silver, platinum, palladium, gold, nickel, aluminum and/or copper.

As indicated above, the nodes (as well as the nanoparticles from which they are derived) preferably are formed of a metallic composition, at least in part. Preferably, the metallic composition comprises a metal selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead.

In other embodiments, the metallic composition comprises an alloy. The alloy may comprise a solid mixture, ordered or disordered, of 2, 3, 4 or more metals. In a preferred aspect, the metallic composition comprises an alloy of at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead. For example, the alloy optionally comprises a combination of metals selected from the group consisting of silver/nickel, silver/copper, silver/cobalt, platinum/copper, platinum/ruthenium, platinum/iridium, platinum/gold, palladium/gold, palladium/silver, nickel/copper, nickel/chromium, and titanium/palladium/gold. In one embodiment, the alloy comprises palladium and silver in a molar ratio of about 3 to about 2, respectively (about 60 mole percent palladium and about 40 mole percent silver). In another aspect, the alloy comprises at least three metals.

Depending on design parameters, the electrical conductor of the present invention may show a resistivity which is not higher than about 30 times, e.g., not higher than about 20 times, not higher than about 10 times, not higher than about 5 times, or not higher than about 3 times the resistivity of the pure bulk metallic phase (alloy or metal).

As mentioned above, and as described in more detail below, the composition of the pore/void structure of the electrical conductors of the present invention may vary widely. In one aspect, at least a portion of the pores or voids are at least partially filled with a composition selected from the group consisting of carbon, alumina, silica, and glass.

In another aspect, at least a portion of the pores or voids are at least partially filled with an organic material, e.g., an organic polymer such as polyvinylpyrrolidone. The polymer preferably comprises units of a monomer, which comprises at least one heteroatom selected from O and N. For example, the polymer optionally comprises units of a monomer which comprises one or more of a hydroxyl group, a carbonyl group, an ether group, an amido group, a carboxyl group, an imido group and an amino group. In another aspect, the polymer comprises units of at least one monomer which comprises a structural element selected from —COO—, —O—CO—O—, —C—O—C—, —CO—O—CO—, —CONR—, —NR—CO—O—, —NR¹—CO—NR²—, —CO—NR—CO—, —SO₂—NR— and —SO₂—O—, wherein R, R¹ and R² independently represent hydrogen or an organic radical.

In several preferred embodiments, the polymer comprises a polymer of vinylpyrrolidone. More preferably, the polymer of vinylpyrrolidone comprises a homopolymer. In other aspects, the polymer of vinylpyrrolidone comprises a copolymer. The copolymer may be selected from the group consisting of a copolymer of vinylpyrrolidone and vinylacetate; a copolymer of vinylpyrrolidone and vinylimidazole; a copolymer of vinylpyrrolidone and styrene; a copolymer of vinylpyrrolidone and 2-dimethylaminoethyl methacrylate; and a copolymer of vinylpyrrolidone and vinylcaprolactam. The polymer optionally is selected from the group consisting of polymers of vinylacetate, polymers of vinylalcohol, polymers of vinylnaphthalene, polymers of vinylphenol, polymers of vinyl N-octadecylcarbamate and polymers of vinylpyridine. These polymers can comprise homopolymers. Additionally or alternatively, these polymers can comprise copolymers. For example the copolymer may be selected from copolymers of vinylacetate, butyl maleate and isobornyl acrylate; copolymers of vinylacetate and crotonic acid; copolymers of vinyl alcohol and ethylene; copolymers of vinyl alcohol, vinyl actetate and itaconic acid; and copolymers of vinyl acetate, vinylalcohol and vinyl butyral. In one aspect, the polymer comprises a mixture of PVP and a PVP copolymer, e.g., the polymer may comprise about 95 wt. % PVP and about 5 wt. % of a PVP copolymer. Such mixtures may advantageously lower the curing/sintering temperature.

As indicated above, the electrical conductor of the present invention preferably has an average pore or void volume of less than about 10,000,000 nm³, e.g., less than about 1,000,000 nm³ or less than about 100,000 nm³. In various other aspects, the pore or void volume is less than about 50,000 nm³, e.g., less than about 20,000 nm³ or less than about 10,000 nm³. In general, lower pore/void volumes are preferred for most conductive applications as the conductivity of the electrical conductor will approach that of the bulk metallic phase as the pore or void volume approaches zero.

That said, the processes of the present invention typically form electrical conductors having a network of pores defined by the network of interconnected nodes. The network of pores may be characterized by the average distance between adjacent pores, the pore size distribution, volume percent of all pores based on the volume of entire electrical conductor, and the average pore volume (of the individual pores), described below. In another embodiment, the electrical conductor comprises a network of “voids” defined by the nanoparticles rather than nodes, as shown in FIG. 3.

The average distance between adjacent pores in the electrical conductor may be determined by, for example, stroboscopic image capture and image analysis on the nanometer scale length. Alternatively, SEM or TEM may be used to determine the average distance between adjacent pores. In various aspects of the present invention, the average distance between adjacent pores in the electrical conductor is from about 0.5 nm to about 500 nm, e.g., from about 1 nm to about 500 nm, from about 1 nm to about 250 nm, from about 1 to about 100 nm or from about 1 to about 50 nm.

It is preferred for the porosity to be evenly distributed so as to reduce unwanted mechanical and physical properties of the conductive feature. Also, the overall porosity should be as fine as possible to achieve initial high sintering rates. The rate at which the pores disappear during sintering should be accompanied by a sufficient rate of reduction in pore size to avoid grain growth.

Additionally, the pore or void network may be described in terms of the total pore/void volume, based on the volume of the electrical conductor as a whole. In various aspects, the electrical conductor comprises the pores or voids in an amount less than about 50 volume percent, e.g., less than about 25 volume percent, less than about 15 volume percent, less than about 10 volume percent or less than about 5 volume percent, based on the total volume of the electrical conductor.

Further, the pores or voids may be characterized as having an ordered arrangement or a disordered (random) arrangement within the electrical conductor. By “ordered arrangement” it is meant that the pores or voids are arranged in the electrical conductor in some repeating pattern. By “disordered arrangement” or “random arrangement” it is meant that the pores or voids are arranged substantially randomly within the electrical conductor.

As discussed in greater detail below, the electrical conductor of the present invention preferably is formed by any of the processes of the present invention. It is contemplated, however, that the compositions of the present invention may also be formed by other heretofore unknown processes, and the present invention is not limited to electrical conductors formed by the processes of the present invention unless expressly so claimed herein.

In a particularly preferred aspect, the electrical conductor of the present invention is formed by a process comprising the steps of: (a) providing an ink comprising metallic nanoparticles and a liquid vehicle; (b) depositing the ink on a substrate; and (c) removing a majority of the liquid vehicle from the deposited ink to form the nodes and the pores in the electrical conductor. Step (c) optionally comprises heating and/or curing the deposited ink under conditions effective to remove the majority of the liquid vehicle, and sinter adjacent metallic nanoparticles to one another to form the nodes and the pores of the electrical conductor.

If the metallic ink used to form the electrical conductor comprises a capping agent (e.g., disposed on a surface of the metallic nanoparticles), the capping agent preferably is removed or transferred away from the surface of the nanoparticles, at least partially, in order to provide increased touching or necking between adjacent metallic nanoparticles. The increased touching facilitates sintering of adjacent nanoparticles. In the case of heating the deposited ink, step (c) preferably comprises heating the ink on the substrate to a maximum temperature of less than about 300° C., less than about 200° C., less than about 125° C., less than about 100° C. or at about ambient temperature.

It will be appreciated that the properties of the electrical conductor may vary depending upon the particular application. For example, where a relatively low conductivity is acceptable it may be desirable for some applications to process the deposited feature at a very low temperature. According to one aspect, a metallic ink may be deposited and processed at a temperature of not greater than 125° C., where the resistivity of the feature is not greater than about 100 times the resistivity of the pure bulk metal, more preferably not greater than about 50 times the resistivity of the bulk metal and even more preferably not greater than about 30 times the resistivity of the bulk metal.

After heating, the compositions of the present invention may yield solids with specific bulk resistivity values. As a background, bulk resistivity values of a number of solids are provided in Table 1.

TABLE 1
BULK RESISTIVITY OF VARIOUS MATERIALS

| | |
|---|---|
| | Bulk Resistivity |
| Material | (micro-Ω cm) |

| | |
|---|---|
| Silver (Ag - thick film material fired at 850° C.) | 1.59 |
| Copper (Cu) | 1.68 |
| Gold (Au) | 2.24 |
| Aluminum (Al) | 2.64 |
| Ferro CN33-246 (Ag + low melting glass, | 2.7-3.2 |
| fired at 150° C.) | |
| SMP Ag flake + metallic nanoparticle | 4.5 |
| formulation, 250° C. | |
| Molybdenum (Mo) | 5.2 |
| Tungsten (W) | 5.65 |
| Zinc (Zn) | 5.92 |
| Nickel (Ni) | 6.84 |
| Iron (Fe) | 9.71 |
| Palladium (Pd) | 10.54 |
| Tin (Sn) | 11 |
| Solder (Pb—Sn; 50:50) | 15 |
| Lead | 20.64 |
| Titanium nitrate (TiN transparent conductor) | 20 |
| 5029 (state of the art Ag filled polymer, 150° C.) | 18-50 |
| DuPont Polymer Thick Film (Cu filled polymer) | 75-300 |
| ITO (In₂O₃:Sn) | 100 |
| Zinc oxide (ZnO doped-undoped) | 120-450 |
| Carbon (C-graphite) | 1375 |
| KIA SCC-10 (doped silver phosphate | 3000 |
| glass, 330° C. soft point) | |
| Ruthenium oxide RuO₂ type conductive oxides | 5000-10,000 |
| Bayer conductive polymer Baytron-P | 1,000,000 |

The compositions and methods of the present invention advantageously allow the fabrication of various unique structures.

In one aspect, the average thickness of the deposited structure (feature) may be greater than about 0.01 μm, e.g., greater than about 0.05 μm, greater than about 0.1 μm, or greater than about 0.5 μm. The thickness can even be greater than about 1 μm, such as greater than about 5 μm. Additionally, the average thickness of the deposited structure (feature) optionally is less than about 50 μm, e.g., less than about 10 μm, less than about 5 μm, or less than about 1 μm. These thicknesses can be obtained by ink-jet deposition or deposition of discrete units of material in a single pass or in two or more passes. For example, a single layer can be deposited and dried, followed by one or more repetitions of this cycle, if desired.

Vias can also be filled with the metallic inks of the present invention. For example, a via can be filled, dried to remove the volume of the solvent, filled further and two or more cycles of this type can be used to fill the via. The via may then be processed to convert the material to its final composition. After conversion, it is also possible to add more metallic ink, dry and then convert the material to product to replace the volume of material lost upon conversion to the final product.

The compositions and methods of the present invention can also be used to form dots, squares and other isolated regions of material. The regions can have a minimum feature size of not greater than about 250 μm, such as not greater than about 100 μm, and even not greater than about 50 μm, such as not greater than about 25 μm, or not greater than about 10 μm. These features can be deposited by ink-jet printing of a single droplet or multiple droplets at the same location with or without drying in between deposition of droplets or periods of multiple droplet deposition. In one aspect, the surface tension of the metallic ink on the substrate material may be chosen to provide poor wetting of the surface so that the composition contracts onto itself after printing. This provides a method for producing deposits with sizes equal to or smaller than the droplet diameter.

The compositions and methods of the present invention can also be used to form lines. In one aspect, the lines can advantageously have an average width of not greater than about 250 μm, such as not greater than about 200 μm, not greater than about 150 μm, not greater than about 100 μm, or not greater than about 50 μm.

In one aspect of the present invention a line may be formed on a substrate by depositing a metallic ink on a substrate in not more than two passes of an ink-jet printing head, e.g., in a single pass of the head, which line can be rendered electrically conductive by heating and/or irradiating the line.

The compositions and methods of the present invention produce features that have good adhesion to substrates of many different materials, e.g., polymeric materials, cellulose-based materials, textiles, glass, metal, silicon and ceramic.

In one aspect, the compositions of the present invention can be used to ink-jet print structures with a specifically targeted structure thickness and sheet resistivity (expressed in Ω/m²). An exact amount of metal (e.g., Ag) per unit area can be printed by adjusting the dots per inch (dpi) data contained in the print file, the inkjet drop volume, and the solid loading of the ink. Multiple pass printing can also be used to print thicker layers. Continuous electrical conductors can be ink-jet printed by adequate drop placement, and by controlling dpi, drop volume, and wetting behavior on the substrate.

In another aspect, the inks and methods of the present invention can also be used to print multilayer structures. For example, an adhesion material/promoter can be printed prior to printing of the metal structure. By way of non-limiting example, in a preferred aspect of the present invention, a metal, metal oxide, or low melting point glass structure may be ink-jet printed on a glass substrate followed by ink-jet printing of a metal (e.g., silver) structure on top of the first printed structure. After heating, the adhesion material/promoter will improve the adhesion of the metal (Ag) structure to the glass substrate. In another non-limiting example, a metal, metal oxide, or low melting point glass structure may be ink-jet printed on an ITO coated glass substrate followed by ink-jet printing of a metal (e.g., silver) structure on top of the first printed structure. After heating, the adhesion material/promoter structure will improve adhesion of the metal structure to the glass substrate.

In another non-limiting example, a black structure may be printed prior to the printing of a metal structure. In a preferred aspect, a carbon containing material and/or a metal oxide (chromium oxide, ruthenium oxide, cobalt oxide, etc.) may be printed in a line on a glass substrate or an ITO coated glass substrate, followed by ink-jet printing of a metal (e.g., silver) line on top of the first printed line. These two printed lines will appear black when viewed through the glass substrate. This is an important feature for flat panel display applications such as plasma displays, where a high contrast ratio between light and dark is required during viewing of the display. In addition, this black structure may in some preferred aspects also enhance the adhesion of the silver layer to the substrate which may be, for example, glass or ITO coated glass.

In yet another non-limiting example, a diffusion barrier material may be printed prior to the printing of the metal (e.g., Ag) structure. By way of non-limiting example, a Ni nanoparticle ink layer may be ink-jet printed on top of a Si substrate (crystalline Si, poly Si, or amorphous Si), for example, an amorphous Si electrode or a poly-Si source or drain of a thin film transistor device in an active matrix backplane of a LCD display. A metal (preferably, silver) line or electrode may be subsequently printed on top of the Ni layer. The Ni layer will provide a diffusion barrier for diffusion of Ag into the Si material. This is important as Si contamination is known to interfere with proper Si transistor device operation. It will be appreciated by those skilled in the art that other diffusion barrier materials can be selected, including materials that react with the silicon layer and form a silicide which acts as a diffusion barrier.

In yet another non-limiting example, a protective layer may be printed on top of the printed metal (e.g., Ag) structure. This protective layer provides protection against, e.g., chemical agents that are present in the gas or liquid to which the printed structure may be exposed after it is printed. For example, a glass or polymer overcoat may be printed on top of a metal (e.g., Ag) structure to prevent oxidation or blackening of the metal due to exposure to the ambient. In another example, a Ni layer may be printed on top of an Ag structure to prevent corrosion of the Ag during subsequent processing steps. Such processing steps may include liquid etching, gas plasma etching, or other processes which are commonly used in the manufacture of transistors and flat panel displays. It will be appreciated by those skilled in the art that other protective overcoat layer materials may be selected as well.

III. Applications

The metallic inks and methods of the present invention may advantageously be used, for example, for the fabrication of printed metallic features which are electrically conductive, and may be transparent, semi-transparent and/or reflective in the visible light range and/or in any other range such as, e.g., in the UV and/or IR ranges. (The terms “feature” and “structure” as used herein and in the appended claims include any two- or three-dimensional structure including, but not limited to, a line, a dot, a patch, a continuous or discontinuous layer (e.g., coating) and in particular, any electrical conductor that is capable of being formed on any substrate.) In particular, the metallic inks and methods of the present invention can be used in a variety of electronic and non-electronic applications such as, e.g., RF ID antennas and tags, digitally printed multi-layer circuit boards, printed membrane keyboards, smart packages, security documents, “disposable electronics” printed on plastics or paper stock, interconnects for applications in printed logic, passive matrix displays, and active matrix backplanes for applications such as OLED displays and TFT AMLCD technology. In the following some non-limiting examples of the types of devices and components to which the methods and compositions of the present invention are applicable will be described in more detail.

The inks and methods of the present invention can be used to fabricate antennas for RF (radio frequency) tags and smart cards. In one aspect, the antenna comprises a material with a sheet resistivity of from about 10 to about 100,000 ohms/square. In another aspect, the antenna comprises a silver conductor with a resistivity that is not greater than three times the resistivity of substantially pure silver.

The compositions can also serve as solder replacements. Such compositions can include silver, lead or tin.

The inks and methods can be utilized to provide connection between chips and other components in smart cards and RF tags.

In one aspect, the surface to be printed onto is not planar and a non-contact printing approach is used. The non-contact printing approach can be ink-jet printing or another technique providing deposition of discrete units of fluid onto the surface. Examples of surfaces that are non-planar include windshields, electronic components, electronic packaging and visors.

The inks and methods provide the ability to print disposable electronics such as for games included in magazines. The inks can advantageously be deposited and reacted on cellulose-based materials such as paper or cardboard. The cellulose-based material can be coated if necessary to prevent bleeding of the metallic ink into the substrate. For example, the cellulose-based material could be coated with a UV curable polymer.

The inks and methods can be used to form under-bump metallization, redistribution patterns and basic circuit components.

The inks and methods of the present invention can also be used to fabricate microelectronic components such as multichip modules, particularly for prototype designs or low-volume production.

Another technology where the direct-write deposition of electronic features according to the present invention provides significant advantages is for flat panel displays, such as plasma display panels. Ink-jet deposition of metal powders is a particularly useful method for forming the electrodes for a plasma display panel. The inks and methods according to the present invention can advantageously be used to form the electrodes, as well as the bus lines and barrier ribs, for the plasma display panel. Typically, a metal paste is printed onto a glass substrate and is fired in air at from about 450° C. to about 600° C. Direct-write deposition of metallic inks offers many advantages over paste techniques including faster production time and the flexibility to produce prototypes and low-volume production applications. The deposited features will have high resolution and dimensional stability, and will have a high density.

Another type of flat panel display is a field emission display (FED). The compositions and methods of the present invention can advantageously be used to deposit the microtip emitters of such a display. More specifically, a direct-write deposition process such as an ink-jet deposition process can be used to accurately and uniformly create the microtip emitters on the backside of the display panel.

The present invention is also applicable to inductor-based devices including transformers, power converters and phase shifters. Examples of such devices are illustrated in, e.g., U.S. Pat. Nos. 5,312,674; 5,604,673 and 5,828,271, the entire disclosures whereof are incorporated by reference herein. In such devices, the inductor is commonly formed as a spiral coil of an electrically conductive trace, typically using a thick-film paste method. To provide the most advantageous properties, the metallized layer, which is typically silver, must have a fine pitch (line spacing). The output current can be greatly increased by decreasing the line width and decreasing the distance between lines. The direct-write process of the present invention is particularly advantageous for forming such devices, particularly when used in a low-temperature co-fired ceramic package (LTCC).

The present invention can also be used to fabricate antennas such as antennas used for cellular telephones. The design of antennas typically involves many trial and error iterations to arrive at the optimum design. The direct-write process of the present invention advantageously permits the formation of antenna prototypes in a rapid and efficient manner, thereby reducing a product development time. Examples of microstrip antennas are illustrated in, e.g., U.S. Pat. Nos. 5,121,127; 5,444,453; 5,767,810 and 5,781,158, the entire disclosures whereof are incorporated herein by reference. The methodology of the present invention can be used to form the conductors of an antenna assembly.

Additional applications of the metallic inks and methods of the present invention include low cost or disposable electronic devices such as electronic displays, electrochromic, electrophoretic and light-emitting polymer-based displays. Other applications include circuits embedded in a wide variety of devices such as low cost or disposable light-emitting diodes, solar cells, portable computers, pagers, cell phones and a wide variety of internet compatible devices such as personal organizers and web-enabled cellular phones.

The inks and methods of the present invention can also produce conductive patterns that can be used in flat panel displays. The conductive materials used for electrodes in display devices have traditionally been manufactured by commercial deposition processes such as etching, evaporation, and sputtering onto a substrate. In electronic displays it is often necessary to utilize a transparent electrode to ensure that the display images can be viewed. Indium tin oxide (ITO), deposited by means of vacuum-deposition or a sputtering process, has found widespread acceptance for this application. For rear electrodes (i.e., the electrodes other than those through which the display is viewed) it is often not necessary to utilize transparent conductors. Rear electrodes can therefore be formed from conventional materials and by conventional processes. Again, the rear electrodes have traditionally been formed using costly sputtering or vacuum deposition methods. The compositions according to the present invention allow the direct deposition of metal electrodes onto low temperature substrates such as plastics. For example, a silver metallic ink can be ink-jet printed and heated at 150° C. to form 150 μm by 150 μm square electrodes with good adhesion and sheet resistivity values.

In one aspect, the metallic inks of the present invention may be used to interconnect electrical elements on a substrate, such as non-linear elements. Non-linear elements are defined herein as electronic devices that exhibit nonlinear responses in relationship to a stimulus. For example, a diode is known to exhibit a nonlinear output-current/input-voltage response. An electroluminescent pixel is known to exhibit a non-linear light-output/applied-voltage response. Nonlinear devices also include, but are not limited to, transistors such as TFTs and OFETs, emissive pixels such as electroluminescent pixels, plasma display pixels, field emission display (FED) pixels and organic light emitting device (OLED) pixels, non emissive pixels such as reflective pixels including electrochromic material, rotatable microencapsulated microspheres, liquid crystals, photovoltaic elements, and a wide range of sensors such as humidity sensors.

Nonlinear elements, which facilitate matrix addressing, are an essential part of many display systems. For a display of M×N pixels, it is desirable to use a multiplexed addressing scheme whereby M column electrodes and N row electrodes are patterned orthogonally with respect to each other. Such a scheme requires only M+N address lines (as opposed to M×N lines for a direct-address system requiring a separate address line for each pixel). The use of matrix addressing results in significant savings in terms of power consumption and cost of manufacture. As a practical matter, the feasibility of using matrix addressing usually hinges upon the presence of a nonlinearity in an associated device. The nonlinearity eliminates crosstalk between electrodes and provides a thresholding function. A traditional way of introducing nonlinearity into displays has been to use a backplane having devices that exhibit a nonlinear current/voltage relationship. Examples of such devices include thin-film transistors (TFT) and metal-insulator-metal (MIM) diodes. While these devices achieve the desired result, they involve thin-film processes, which suffer from high production costs as well as relatively poor manufacturing yields.

The present invention allows the direct printing of the conductive components of nonlinear devices including the source, the drain and the gate. These nonlinear devices may include directly printed organic materials such as organic field effect transistors (OFET) or organic thin film transistors (OTFT), directly printed inorganic materials and hybrid organic/inorganic devices such as a polymer based field effect transistor with an inorganic gate dielectric. Direct printing of these conductive materials will enable low cost manufacturing of large area flat displays.

The inks and methods of the present invention are capable of producing conductive patterns that can be used in flat panel displays to form, e.g., the address lines or data lines. The present invention provides ways to form address and data lines using deposition tools such as an ink-jet device. The metallic inks of the present invention allow printing on large area flexible substrates such as plastic substrates and paper substrates, which are particularly useful for large area flexible displays. Address lines may additionally be insulated with an appropriate insulator such as a non-conducting polymer or other suitable insulator. Alternatively, an appropriate insulator may be formed so that there is electrical isolation between row conducting lines, between row and column address lines, between column address lines or for other purposes. By way of non-limiting example, these lines can be printed with a thickness of, e.g., about one μm and a line width of about 100 μm by ink-jet printing the metallic ink. These data lines can be printed continuously on large substrates with an uninterrupted length of several meters. Surface modification can be employed, as is discussed above, to confine the composition and to enable printing of lines as narrow as about 10 μm. The deposited lines can be heated to about 200° C. to form metal lines with a bulk conductivity that is not less than about 10 percent of the conductivity of the equivalent pure metal.

Flat panel displays may incorporate emissive or reflective pixels. Some examples of emissive pixels include electroluminescent pixels, photoluminescent pixels such as plasma display pixels, field emission display (FED) pixels and organic light emitting device (OLED) pixels. Reflective pixels include contrast media that can be altered using an electric field. Contrast media may be electrochromic material, rotatable microencapsulated microspheres, polymer dispersed liquid crystals (PDLCs), polymer stabilized liquid crystals, surface stabilized liquid crystals, smectic liquid crystals, ferroelectric material, or other contrast media well known in art. Many of these contrast media utilize particle-based non-emissive systems. Examples of particle-based non-emissive systems include encapsulated electrophoretic displays (in which particles migrate within a dielectric fluid under the influence of an electric field); electrically or magnetically driven rotating-ball displays as disclosed in, e.g., U.S. Pat. Nos. 5,604,027 and 4,419,383, which are incorporated herein by reference in their entireties; and encapsulated displays based on micromagnetic or electrostatic particles as disclosed in, e.g., U.S. Pat. Nos. 4,211,668, 5,057,363 and 3,683,382, which are incorporated by reference herein in their entireties. A preferred particle non-emissive system is based on discrete, microencapsulated electrophoretic elements, examples of which are disclosed in U.S. Pat. No. 5,930,026 which is incorporated by reference herein in its entirety.

In another aspect, the present invention relates to the direct printing of electrical conductors, such as electrical interconnects and electrodes for addressable, reusable, paper-like visual displays. Examples of paper-like visual displays include “gyricon” (or twisting particle) displays and forms of electronic paper such as particulate electrophoretic displays (available from E-ink Corporation, Cambridge, Mass.). A gyricon display is an addressable display made up of optically anisotropic particles, with each particle being selectively rotatable to present a desired face to an observer. For example, a gyricon display can incorporate “balls” where each ball has two distinct hemispheres, one black and the other white. Each hemisphere has a distinct electrical characteristic (e.g., zeta potential with respect to a dielectric fluid) so that the ball is electrically as well as optically anisotropic. The balls are electrically dipolar in the presence of a dielectric fluid and are subject to rotation. A ball can be selectively rotated within its respective fluid-filled cavity by application of an electric field, so as to present either its black or white hemisphere to an observer viewing the surface of the sheet.

In a preferred aspect, a metal electrode may be printed for the purpose of charge injection into a conducting or semiconducting polymer layer. For many applications, it is preferred that this metal electrode has a work function that is matched to the work function of the polymer. In a preferred aspect, a printed Ni electrode with a work function of more than 5 eV is used to ink-jet charge carriers into a conducting polymer layer, for example a source electrode or a drain electrode layer.

In another aspect, the present invention relates to electrical interconnects and electrodes for organic light emitting displays (OLEDs). Organic light emitting displays are emissive displays consisting of a transparent substrate coated with a transparent conducting material (e.g., ITO), one or more organic layers and a cathode made by evaporating or sputtering a metal of low work function characteristics (e.g., calcium or magnesium). The organic layer materials are chosen so as to provide charge injection and transport from both electrodes into the electroluminescent organic layer (EL), where the charges recombine to emit light. There may be one or more organic hole transport layers (HTL) between the transparent conducting material and the EL, as well as one or more electron injection and transporting layers between the cathode and the EL. The metallic inks according to the present invention allow the direct deposition of metal electrodes onto low temperature substrates such as flexible large area plastic substrates that are particularly preferred for OLEDs. For example, a metallic ink of the present invention may be ink-jet printed and heated at 150° C. to form a 150 μm by 150 μm square electrode with good adhesion and a sheet resistivity. The compositions and printing methods of the present invention also enable printing of row and column address lines for OLEDs. These lines can be printed with a thickness of about one μm and a line width of about 100 μm using ink-jet printing. These data lines can be printed continuously on large substrates with an uninterrupted length of several meters. Surface modification can be employed, as is discussed above, to confine the metallic ink and to enable printing of such lines as narrow as about 10 μm. The printed ink lines can be heated to, e.g., about 150° C. and form metal lines with a bulk conductivity that is at least about 5 percent of the conductivity of the equivalent pure metal or metallic phase.

In a particularly preferred aspect of the present invention, an optically reflective metal anode may be ink-jet printed using a silver nanoparticle ink. The top emission anode may be printed on top of an organic layer and processed at a temperature below about 180° C. and for a period of less than 5 minutes so that the organic layer does not get damaged. A layer comprising a light-emitting polymer may be printed on top of this electrode. This emission anode may be less than about 200 micrometer wide and may be used for charge injection into said light emitting polymer. The electrode may be reflective to ensure that light generated in the OLED device stack is reflected back towards the viewer.

In another aspect, the present invention relates to electrical interconnects and electrodes for liquid crystal displays (LCDs), including passive-matrix and active-matrix. Particular examples of LCDs include twisted nematic (TN), supertwisted nematic (STN), double supertwisted nematic (DSTN), retardation film supertwisted nematic (RFSTN), ferroelectric (FLCD), guest-host (GHLCD), polymer-dispersed (PD), polymer network (PN).

Thin film transistors (TFTs) are well known in the art, and are of considerable commercial importance. Amorphous silicon-based thin film transistors are used in active matrix liquid crystal displays. One advantage of thin film transistors is that they are inexpensive to make, both in terms of the materials and the techniques used to make them. In addition to making the individual TFTs as inexpensively as possible, it is also desirable to inexpensively make the integrated circuit devices that utilize TFTs. Accordingly, inexpensive methods for fabricating integrated circuits with TFTs, such as those of the present invention, are an enabling technology for printed logic.

For many applications, inorganic interconnects are not adequately conductive to achieve the desired switching speeds of an integrated circuit due to high RC time constants. Printed pure metals, as enabled by the metallic inks of the present invention, achieve the required performance. By way of non-limiting example, a metal interconnect printed by using a silver metallic ink as provided by the present invention may result in a reduction of the resistance (R) and an associated reduction in the time constant (RC) by a factor of about 100,000, or even by a factor of about 1,000,000, as compared to current conductive polymer interconnect materials used to connect polymer transistors.

Field-effect transistors (FETs), with organic semiconductors as active materials, are the key switching components in contemplated organic control, memory, or logic circuits, also referred to as plastic-based circuits. An expected advantage of such plastic electronics is the ability to fabricate them more easily than traditional silicon-based devices. Plastic electronics thus provide a cost advantage in cases where it is not necessary to attain the performance level and device density provided by silicon-based devices. For example, organic semiconductors are expected to be much more readily printable than vapor-deposited inorganics, and are also expected to be less sensitive to air than recently proposed solution-deposited inorganic semiconductor materials. For these reasons, there have been significant efforts expended in the area of organic semiconductor materials and devices.

Organic thin film transistors (TFTs) are expected to become key components in the plastic circuitry used in display drivers of portable computers and pagers, and memory elements of transaction cards and identification tags. A typical organic TFT circuit contains a source electrode, a drain electrode, a gate electrode, a gate dielectric, an interlayer dielectric, electrical interconnects, a substrate, and semiconductor material. The metallic inks of the present invention may be used to deposit several of the components of this circuit. Of course, the metallic inks of the present invention may also be used to form inorganic TFTs.

One of the most significant factors in bringing organic TFT circuits into commercial use is the ability to deposit all the components on a substrate quickly, easily and inexpensively as compared with silicon technology (i.e., by reel-to-reel printing). The metallic inks of the present invention enable the use of low cost deposition techniques, such as ink-jet printing, for depositing these components.

Metallic inks are particularly useful for the direct printing of electrical connectors as well as antennae of smart tags, smart labels, and a wide range of identification devices such as radio frequency identification (RFID) tags. In a broad sense, the metallic inks can be utilized for electrical connection of semiconductor radio frequency transceiver devices to antenna structures and particularly to radio frequency identification device assemblies. A radio frequency identification device (“RFID”) by definition is an automatic identification and data capture system comprising readers and tags. Data is transferred using electric fields or modulated inductive or radiating electromagnetic carriers. RFID devices are becoming more prevalent in such configurations as, for example, smart cards, smart labels, security badges, and livestock tags. Other types of electronic surveillance tags or articles may be manufactured using the metallic inks, which articles do not require transistor logic but can be fabricated by using metal connects and a dielectric (such as a capacitive element).

Metallic inks also enable the low cost, high volume, highly customizable production of electronic labels. Such labels can be formed in various sizes and shapes for collecting, processing, displaying and/or transmitting information related to an item in human or machine readable form. The metallic inks of the present invention can be used to print the electrical conductors required for forming, e.g., the logic circuits, electronic interconnections and antennae in electronic labels. The electronic labels can be an integral part of a larger printed item such as a lottery ticket structure with circuit elements disclosed in a pattern as disclosed in U.S. Pat. No. 5,599,046, the entire disclosure whereof is incorporated by reference herein.

In another aspect of the present invention, the conductive patterns made in accordance with the present invention can be used as electronic circuits for making photovoltaic panels. Screen-printing is conventionally used in mass scale production of solar cells. Typically, the top contact pattern of a solar cell consists of a set of parallel narrow finger lines and wide collector lines deposited essentially at a right angle to the finger lines on a semiconductor substrate or wafer. Such front contact formation of crystalline solar cells is performed with standard screen-printing techniques. Direct printing of these contacts with the metallic inks of the present invention provides the advantages of production simplicity, automation, and low production cost.

Low series resistance and low metal coverage (low front surface shadowing) are basic requirements for the front surface metallization in solar cells. Minimum metallization widths of about 100 to about 150 μm are obtained using conventional screen-printing. This causes a relatively high shading of the front solar cell surface. In order to decrease the shading, a large distance between the contact lines, i.e., 2 to 3 mm is required. On the other hand, this implies the use of a highly doped, conductive emitter layer. However, the heavy emitter doping induces a poor response to short wavelength light. Narrower conductive lines may be printed using the metallic inks and printing methods of the present invention. The metallic inks of the present invention may enable direct printing of finer features down to about 50 μm. The metallic inks of the present invention further may enable the printing of pure metals with resistivity values of the printed features as low as 2 times the bulk resistivity after processing at temperatures as low as about 200° C.

The low processing and direct-write deposition capabilities according to the present invention are suitable also for large area solar cell manufacturing on organic and flexible substrates. This is particularly useful in manufacturing novel solar cell technologies based on organic photovoltaic materials such as organic semiconductors and dye sensitized solar cell technology as disclosed in U.S. Pat. No. 5,463,057, the entire disclosure whereof is incorporated by reference herein. The metallic inks according to the present invention can be directly printed and heated to yield a bulk conductivity that may be no less than about 10 percent of the conductivity of the equivalent pure metal (or metallic phase), and achieved by heating the printed features at temperatures below about 200° C. on polymer substrates such as plexiglass (PMMA).

Another aspect of the present invention comprises the production of an electronic circuit for making printed wiring board (PWBs) and printed circuit boards (PCBs). In conventional subtractive processes used to make printed-wiring boards, wiring patterns are formed by preparing pattern films. The pattern films are prepared by means of a laser plotter in accordance with wiring pattern data outputted from a CAD (computer-aided design system), and are etched on copper foil by using a resist ink or a dry film resist. In such conventional processes, it is necessary to first form a pattern film, and to prepare a printing plate in the case when a photo-resist ink is used, or to take the steps of lamination, exposure and development in the case when a dry film resist is used.

Such methods can be said to be methods in which the digitized wiring data are returned to an analog image-forming step. Screen-printing has a limited work size because of the printing precision of the printing plate. The dry film process is a photographic process and, although it provides high precision, it requires many steps, resulting in a high cost especially for the manufacture of small lots.

The metallic inks and methods of the present invention offer solutions to overcome the limitations of the current PWB formation process. For example, they typically do not generate any waste. The methods of the present invention may be a single step direct printing process and are compatible with small-batch and rapid turn around production runs. For example, a copper nanoparticle composition can be directly printed onto FR4 (an epoxy resin impregnated fiberglass) to form interconnection circuitry. These features are formed by heating printed copper nanoparticles in an N₂ ambient at about 150° C. to form copper lines with a line width of not greater than about 100 μm, a line thickness of not greater than about 5 μm, and a bulk conductivity that is at least about 10 percent of the conductivity of the pure copper metal.

In another non-limiting example, Ag may be ink-jet printed on a PCB (printed circuit board) and used as a seed layer for Cu electroplating or electroless deposition of Cu. Ag may also be used to ink-jet print electrodes for embedded passives for PCBs.

Patterned electrodes obtained by one aspect of the present invention can also be used for screening electromagnetic radiation or earthing electric charges, in making touch screens, radio frequency identification tags, electrochromic windows and in imaging systems, e.g., silver halide photography or electrophotography. A device such as the electronic book described in U.S. Pat. No. 6,124,851, the entire disclosure whereof is incorporated by reference herein, can also be formed using the compositions of the present invention.

In addition, metallic nanoparticles (e.g., silver nanoparticles) having a size of less than about 100 nm have outstanding optical characteristics in that they are perfectly reflective, i.e., do not diffract incident light, resulting in a perfect mirror finish on articles onto which they are applied. This is a valuable property for, e.g., graphic and mirror applications.

IV. Processes for Forming the Electrical Conductors

As indicated above, the electrical conductors of the present invention may be formed by a variety of processes. In a preferred aspect of the invention, the electrical conductors are formed by a process comprising the steps of: (a) providing an ink comprising metallic nanoparticles and a liquid vehicle; (b) depositing the ink on a substrate; and (c) removing a majority of the liquid vehicle from the deposited ink to form the nodes and the pores in the electrical conductor. In one aspect, step (c) comprises heating the deposited ink under conditions effective to remove the majority of the liquid vehicle, and sinter adjacent metallic nanoparticles to one another to form the nodes and the pores of the electrical conductor, as shown in FIG. 4. Alternatively, step (c) may occur under milder conditions causing a majority of the nanoparticles to touch at least one adjacent nanoparticle, as shown in FIG. 3, but not substantially sinter together to form nodes.

A. Ink Compositions

An ink from which the electrical conductor of the present invention is formed is referred to herein as a “metallic ink” although the ink may or may not have metallic properties. The metallic ink may comprise a variety of different components. In a preferred aspect, the ink comprises metallic nanoparticles. Additionally, the metallic ink preferably comprises a liquid vehicle in an amount sufficient to impart flowability to the ink. In various embodiments, the ink may comprise one or more of the following: metal precursors, substrate precursors, fusing agents, additives, and/or other components. Each of these components will now be described in turn.

1. Metallic Nanoparticles

In a preferred embodiment, the metallic ink from which the electrical conductor of the present invention is formed comprises metallic nanoparticles. The metallic nanoparticles used to form the conductors of the present invention preferably comprise a metallic composition that exhibits a low bulk resistivity such as, e.g., a bulk resistivity of less than about 15 micro-Ωcm, e.g., less than about 10 micro-Ωcm, or less than about 5 micro-Ωcm.

The metallic nanoparticles comprise one or more metals in elemental or alloy form. Thus, the metallic nanoparticles comprise a metallic composition. The metallic composition preferably comprises a metal selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead. In another aspect, the metal includes one or more transition metals as well as main group metals such as, e.g., silver, gold, copper, nickel, cobalt, palladium, platinum, indium, tin, zinc, titanium, chromium, tantalum, tungsten, iron, rhodium, iridium, ruthenium, osmium, aluminum and lead. Non-limiting examples of preferred metals for use in the present invention include silver, gold, copper, nickel, cobalt, rhodium, palladium and platinum. Silver, copper and nickel are particularly preferred metals for the purposes of the present invention, silver being particularly preferred.

The metallic ink also may comprise mixtures of two or more different metallic nanoparticles and/or may comprise nanoparticles wherein two or more metals are present in a single nanoparticle, for example, in the form of an alloy or a mixture of these metals. Thus, the nanoparticles may comprise a metallic composition, which comprises an alloy. The alloy may comprise a solid mixture, ordered or disordered, of 2, 3, 4 or more metals. Non-limiting examples of alloys include Ag/Ni, Ag/Cu, Pt/Cu, Ru/Pt, Ir/Pt and Ag/Co. In a preferred aspect, the alloy comprises at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead. For example, the alloy optionally comprises a combination of metals selected from the group consisting of silver/nickel, silver/copper, silver/cobalt, platinum/copper, platinum/ruthenium, platinum/iridium, platinum/gold, palladium/gold, palladium/silver, nickel/copper, nickel/chromium, and titanium/palladium/gold.

Also, the nanoparticles may have a core-shell structure made of two different metals such as, e.g., a core of silver and a shell of nickel (e.g., a silver core having a diameter of about 20 nm surrounded by an about 15 nm thick nickel shell).

In a preferred aspect, a capping agent is present on the metallic nanoparticles, at least while in ink form, to inhibit substantial agglomeration of the nanoparticles. Due to their small size and the high surface energies associated therewith, nanoparticles usually show a strong tendency to agglomerate and form larger secondary particles (agglomerates). The capping agent shields (e.g., sterically and/or through charge effects) the nanoparticles from each other to at least some extent and thereby substantially prevents a direct contact between individual nanoparticles. The capping agent is preferably adsorbed on the surface of the metallic nanoparticles. The term “adsorbed” as used herein includes any kind of interaction between the capping agent and a nanoparticle surface (e.g., the metal atoms on the surface of a nanoparticle) that manifests itself in an at least (and preferably) weak bond between the capping agent and the surface of a nanoparticle. The capping agent may be chemically or physically adsorbed on the surface of the nanoparticles. In one aspect, the bond is a non-covalent bond, but still strong enough for the nanoparticle/capping agent combination to withstand a washing operation with a solvent that is capable of dissolving the capping agent. In other words, merely washing the metallic nanoparticles with the solvent at room temperature will preferably not remove more than a minor amount (e.g., less than about 10%, less than about 5%, or less than about 1%) of the capping agent that is in intimate contact with (and (weakly) bonded to) the nanoparticle surface. Of course, any capping agent that is not in intimate contact with a nanoparticle surface but merely accompanies the bulk of the nanoparticles (e.g., as an impurity/contaminant), i.e., without any significant interaction therewith, will preferably be removable from the nanoparticles by washing the latter with a solvent for the capping agent. In another aspect, the capping agent, e.g., PVP, is covalently bonded to at least a portion of the surface of the metallic nanoparticles.

The capping agent does not have to be present as a continuous coating (shell) on the entire surface of the metallic nanoparticles. Rather, in order to prevent substantial agglomeration of the nanoparticles it will often be sufficient for the capping agent to be present on only a part of the surface of the metallic nanoparticles.

While the capping agent will usually be a single substance or at least comprise two or more substances of the same type, the present invention also contemplates the use of two or more different types of capping agents. For example, a mixture of two or more different low molecular weight compounds or a mixture of two or more different polymers may be used, as well as a mixture of one or more low molecular weight compounds and one or more polymers. The term “capping agent” as used herein includes all of these possibilities.

A preferred and non-limiting example of a capping agent for use in the present invention includes a substance that is capable of electronically interacting with a metal atom of a nanoparticle. Usually, a substance that is capable of this type of interaction will comprise one or more atoms (e.g., one or two atoms) with one or more lone electron pairs such as, e.g., oxygen, nitrogen and sulfur. Particularly preferred capping agents comprise one or two 0 and/or N atoms (per monomer unit in the case of a polymer). The atoms with a lone electron pair will usually be present in the substance in the form of a functional group such as, e.g., a hydroxy group, a carbonyl group, an ether group, an amido group, a carboxylic group, and an amino group, or as a constituent of a functional group that comprises one or more of these groups as a structural element thereof. Non-limiting examples of functional groups include —COO—, —O—CO—O—, —CO—O—CO—, —C—O—C—, —CONR—, —NR—CO—O—, —NR¹—CO—NR²—, —CO—NR—CO—, —SO₂—NR— and —SO₂—O—, wherein R, R¹ and R² independently represent hydrogen or an organic radical (e.g., an aliphatic or aromatic, unsubstituted or substituted radical comprising from about 1 to about 20 carbon atoms). Such functional groups may comprise the above (and other) structural elements as part of a cyclic structure (e.g., in the form of a cyclic ester, amide, anhydride, imide, carbonate, urethane, urea, and the like).

The capping agent may be inorganic or organic and may comprise a low molecular weight compound, preferably a low molecular weight organic compound, e.g., a compound having a molecular weight of not higher than about 500, more preferably not higher than about 300, and/or may comprise an oligomeric or polymeric, preferably organic compound having a (weight average) molecular weight of at least about 1,000, for example, at least about 3,000, at least about 5,000, or at least about 8,000, but preferably not higher than about 500,000, e.g., not higher than about 200,000, or not higher than about 100,000. By way of non-limiting example, in the case of polyvinylpyrrolidone, which is a non-limiting example of a preferred capping agent for use in the present invention, the preferred weight average molecular weight is in the range of from about 3,000 to about 60,000 and a particularly preferred average molecular weight is about 10,000.

Non-limiting examples of the low molecular weight capping agent for use in the present invention include fatty acids, in particular, fatty acids having at least about 8 carbon atoms. Non-limiting examples of oligomers/polymers for use as the capping agent in the process of the present invention include homo- and copolymers (including polymers such as, e.g., random copolymers, block copolymers and graft copolymers) which comprise units of at least one monomer which comprises one or more O atoms and/or one or more N atoms. A non-limiting class of preferred polymers for use as capping agent in the present invention are polymers that form a dative bond to the metallic nanoparticle surface. Such a dative bond is advantageously weak enough to break during heating after the nanoparticles have been applied to a substrate (e.g., by ink-jet printing). This bond breakage thereby enables the nanoparticles to touch, neck and sinter to form a conductive network, without the need to remove the polymer from the printed layer by combustion or volatilization. Another non-limiting class of preferred polymers for use in the present invention (which overlaps with the former class of preferred polymers) is constituted by polymers which comprise at least one monomer unit which includes at least two atoms which are selected from O and N atoms. Corresponding monomer units may, for example, comprise at least one hydroxyl group, carbonyl group, ether linkage, amido group, carboxyl group, imido group and/or amino group and/or one or more structural elements of formula —COO—, —O—CO—O—, —CO—O—CO—, —C—O—C—, —CONR—, —NR—CO—O—, —NR¹—CO—NR²—, —CO—NR—CO—, —SO₂—NR— and —SO₂—O—, wherein R, R¹ and R² independently represent hydrogen or an organic radical (e.g., an aliphatic or aromatic, unsubstituted or substituted radical comprising from about 1 to about 20 carbon atoms).

Non-limiting examples of corresponding polymers include polymers which comprise one or more units derived from the following groups of monomers:

(a) monoethylenically unsaturated carboxylic acids of from about 3 to about 8 carbon atoms and salts thereof. This group of monomers includes, for example, acrylic acid, methacrylic acid, dimethylacrylic acid, ethacrylic acid, maleic acid, citraconic acid, methylenemalonic acid, allylacetic acid, vinylacetic acid, crotonic acid, fumaric acid, mesaconic acid and itaconic acid. The monomers of group (a) can be used either in the form of the free carboxylic acids or in partially or completely neutralized form. For the neutralization alkali metal bases, alkaline earth metal bases, ammonia or amines, e.g., sodium hydroxide, potassium hydroxide, sodium carbonate, potassium carbonate, sodium bicarbonate, magnesium oxide, calcium hydroxide, calcium oxide, ammonia, triethylamine, methanolamine, diethanolamine, triethanolamine, morpholine, diethylenetriamine or tetraethylenepentamine may, for example, be used;

(b) the esters, amides, anhydrides and nitriles of the carboxylic acids stated under (a) such as, e.g., methyl acrylate, ethyl acrylate, methyl methacrylate, ethyl methacrylate, n-butyl acrylate, hydroxyethyl acrylate, 2- or 3-hydroxypropyl acrylate, 2- or 4-hydroxybutyl acrylate, hydroxyethyl methacrylate, 2- or 3-hydroxypropyl methacrylate, hydroxyisobutyl acrylate, hydroxyisobutyl methacrylate, monomethyl maleate, dimethyl maleate, monoethyl maleate, diethyl maleate, maleic anhydride, 2-ethylhexyl acrylate, 2-ethylhexyl methacrylate, acrylamide, methacrylamide, N,N-dimethylacrylamide, N-tert-butylacrylamide, acrylonitrile, methacrylonitrile, 2-dimethylaminoethyl acrylate, 2-dimethylaminoethyl methacrylate, 2-diethylaminoethyl acrylate, 2-diethylaminoethyl methacrylate and the salts of the last-mentioned monomers with carboxylic acids or mineral acids and the quaternized products;

(c) acrylamidoglycolic acid, vinylsulfonic acid, allylsulfonic acid, methallylsulfonic acid, styrenesulfonic acid, 3-sulfopropyl acrylate, 3-sulfopropyl methacrylate and acrylamidomethylpropanesulfonic acid and monomers containing phosphonic acid groups, such as, e.g., vinyl phosphate, allyl phosphate and acrylamidomethylpropanephosphonic acid; and esters, amides and anhydrides of these acids;

(d) N-vinyllactams such as, e.g., N-vinylpyrrolidone, N-vinyl-2-piperidone and N-vinylcaprolactam; and

(e) vinyl acetal, vinyl butyral, vinyl alcohol and ethers and esters thereof (such as, e.g., vinyl acetate, vinyl propionate and methylvinylether), allyl alcohol and ethers and esters thereof, N-vinylimidazole, N-vinyl-2-methylimidazoline, and the hydroxystyrenes.

Corresponding polymers may also contain additional monomer units, for example, units derived from monomers without functional group, halogenated monomers, aromatic monomers etc. Non-limiting examples of such monomers include olefins such as, e.g., ethylene, propylene, the butenes, pentenes, hexenes, octenes, decenes and dodecenes, styrene, vinyl chloride, vinylidene chloride, tetrafluoroethylene, etc. Further, the polymers for use as adsorptive substance in the process of the present invention are not limited to addition polymers, but also comprise other types of polymers, for example, condensation polymers such as, e.g., polyesters, polyamides, polyurethanes and polyethers, as well as polysaccharides such as, e.g., starch, cellulose and derivatives thereof, etc.

Other non-limiting examples of polymers which are suitable for use as capping agents (e.g., anti-agglomerating agents) in the present invention are disclosed in, e.g., U.S. Patent Application Publication 2004/0182533 A1, the entire disclosure whereof is expressly incorporated by reference herein.

Preferred polymers for use as the capping agent in the present invention include those which comprise units derived from one or more N-vinylcarboxamides of formula (I)
CH₂═CH—NR³—CO—R⁴ (I)
wherein R³ and R⁴ independently represent hydrogen, optionally substituted alkyl (including cycloalkyl) and optionally substituted aryl (including alkaryl and aralkyl) or heteroaryl (e.g., C₆₋₂₀ aryl such as phenyl, benzyl, tolyl and phenethyl, and C₄₋₂₀ heteroaryl such as pyrrolyl, furyl, thienyl and pyridinyl).

R³ and R⁴ may, e.g., independently represent hydrogen or C₁₋₁₂ alkyl, particularly C₁₋₆ alkyl such as methyl and ethyl. R³ and R⁴ together may also form a straight or branched chain containing from about 2 to about 8, preferably from about 3 to about 6, particularly preferably from about 3 to about 5 carbon atoms, which chain links the N atom and the C atom to which R³ and R⁴ are bound to form a ring which preferably has about 4 to about 8 ring members. Optionally, one or more carbon atoms may be replaced by heteroatoms such as, e.g., oxygen, nitrogen or sulfur. Also optionally, the ring may contain a carbon-carbon double bond.

Non-limiting specific examples of R³ and R⁴ are methyl, ethyl, isopropyl, n-propyl, n-butyl, isobutyl, sec-butyl, tert-butyl, n-hexyl, n-heptyl, 2-ethylhexyl, n-octyl, n-decyl, n-undecyl, n-dodecyl, n-tetradecyl, n-hexadecyl, n-octadecyl and n-eicosyl. Non-limiting specific examples of R³ and R⁴ which together form a chain are 1,2-ethylene, 1,2-propylene, 1,3-propylene, 2-methyl-1,3-propylene, 2-ethyl-1,3-propylene, 1,4-butylene, 1,5-pentylene, 2-methyl-1,5-pentylene, 1,6-hexylene and 3-oxa-1,5-pentylene.

Non-limiting specific examples of N-vinylcarboxamides of formula (I) are N-vinylformamide, N-vinylacetamide, N-vinylpropionamide, N-vinylbutyramide, N-vinylisobutyramide, N-vinyl-2-ethylhexanamide, N-vinyldecanamide, N-vinyldodecanamide, N-vinylstearamide, N-methyl-N-vinylformamide, N-methyl-N-vinylacetamide, N-methyl-N-vinylpropionamide, N-methyl-N-vinylbutyramide, N-methyl-N-vinylisobutyramide, N-methyl-N-vinyl-2-ethylhexanamide, N-methyl-N-vinyldecanamide, N-methyl-N-vinyldodecanamide, N-methyl-N-vinylstearamide, N-ethyl-N-vinylformamide, N-ethyl-N-vinylacetamide, N-ethyl-N-vinylpropionamide, N-ethyl-N-vinylbutyramide, N-ethyl-N-vinylisobutyramide, N-ethyl-N-vinyl-2-ethylhexanamide, N-ethyl-N-vinyldecanamide, N-ethyl-N-vinyldodecanamide, N-ethyl-N-vinylstearamide, N-isopropyl-N-vinylformamide, N-isopropyl-N-vinylacetamide, N-isopropyl-N-vinylpropionamide, N-isopropyl-N-vinylbutyramide, N-isopropyl-N-vinylisobutyramide, N-isopropyl-N-vinyl-2-ethylhexanamide, N-isopropyl-N-vinyldecanamide, N-isopropyl-N-vinyldodecanamide, N-isopropyl-N-vinylstearamide, N-n-butyl-N-vinylformamide, N-n-butyl-N-vinylacetamide, N-n-butyl-N-vinylpropionamide, N-n-butyl-N-vinylbutyramide, N-n-butyl-N-vinylisobutyramide, N-n-butyl-N-vinyl-2-ethylhexanamide, N-n-butyl-N-vinyldecanamide, N-n-butyl-N-vinyldodecanamide, N-n-butyl-N-vinylstearamide, N-vinylpyrrolidone, N-vinyl-2-piperidone and N-vinylcaprolactam.

Particularly preferred polymers for use as capping agent in the present invention include polymers which comprise monomer units of one or more unsubstituted or substituted N-vinyllactams, preferably those having from about 4 to about 8 ring members such as, e.g., N-vinylcaprolactam, N-vinyl-2-piperidone and N-vinylpyrrolidone. These polymers include homo- and copolymers. In the case of copolymers (including, for example, random, block and graft copolymers), the N-vinyllactam (e.g., N-vinylpyrrolidone) units are preferably present in an amount of at least about 10 mole-%, e.g., at least about 30 mole-%, at least about 50 mole-%, at least about 70 mole-%, at least about 80 mole-%, or at least about 90 mole-%. By way of non-limiting example, the comonomers may comprise one or more of those mentioned in the preceding paragraphs, including monomers without functional group (e.g., ethylene, propylene, styrene, etc.), halogenated monomers, etc.

If the vinyllactam (e.g., vinylpyrrolidone) monomers (or at least a part thereof) carry one or more substituents on the heterocyclic ring, non-limiting examples of such substituents include alkyl groups (for example, alkyl groups having from 1 to about 12 carbon atoms, e.g., from 1 to about 6 carbon atoms such as, e.g., methyl, ethyl, propyl and butyl), alkoxy groups (for example, alkoxy groups having from 1 to about 12 carbon atoms, e.g., from 1 to about 6 carbon atoms such as, e.g., methoxy, ethoxy, propoxy and butoxy), halogen atoms (e.g., F, Cl and Br), hydroxy, carboxy and amino groups (e.g., dialkylamino groups such as dimethylamino and diethylamino) and any combinations of these substituents.

Non-limiting specific examples of vinyllactam polymers for use in the present invention include homo- and copolymers of vinylpyrrolidone which are commercially available from, e.g., International Specialty Products (www.ispcorp.com). In particular, these polymers include:

(a) vinylpyrrolidone homopolymers such as, e.g., grades K-15 and K-30 with K-value ranges of from 13-19 and 26-35, respectively, corresponding to average molecular weights (determined by GPC/MALLS) of about 10,000 and about 67,000;

(b) alkylated polyvinylpyrrolidones such as, e.g., those commercially available under the trade mark GANEX® which are vinylpyrrolidone-alpha-olefin copolymers that contain most of the alpha-olefin (e.g., about 80% and more) grafted onto the pyrrolidone ring, mainly in the 3-position thereof; the alpha-olefins may comprise those having from about 4 to about 30 carbon atoms; the alpha-olefin content of these copolymers may, for example, be from about 10% to about 80% by weight;

(c) vinylpyrrolidone-vinylacetate copolymers such as, e.g., random copolymers produced by a free-radical polymerization of the monomers in a molar ratio of from about 70/30 to about 30/70 and having weight average molecular weights of from about 14,000 to about 58,000;

(d) vinylpyrrolidone-dimethylaminoethylmethacrylate copolymers;

(e) vinylpyrrolidone-methacrylamidopropyl trimethylammonium chloride copolymers such as, e.g., those commercially available under the trade mark GAFQUAT®;

(f) vinylpyrrolidone-vinylcaprolactam-dimethylaminoethylmethacrylate terpolymers such as, e.g., those commercially available under the trade mark GAFFIX®;

(g) vinylpyrrolidone-styrene copolymers such as, e.g., those commercially available under the trade mark POLECTRON®; a specific example thereof is a graft emulsion copolymer of about 70% vinylpyrrolidone and about 30% styrene polymerized in the presence of an anionic surfactant; and

(h) vinylpyrrolidone-acrylic acid copolymers such as, e.g., those commercially available under the trade mark ACRYLIDONE® which are produced in the molecular weight range of from about 80,000 to about 250,000.

Other non-limiting specific examples of vinyllactam polymers for use in the present invention include homo- and copolymers of vinylpyrrolidone which are commercially available from, e.g., BASF. In particular, these polymers include:

(a) vinylpyrrolidone homopolymers such as, e.g., grades K-17, K-30, K-80, K-85, K-90, K-90 HM, K-30, K-60, K-85 CQ, K-90 and K-115 CQ, commercially available under the trademark Luvitec; and

(b) Vinylpyrrolidone copolymers such as, e.g., grades VA 64 W or VA 64, vinylpyrrolidone-vinylacetate, VPI 55 K 72 W, vinylpyrrolidone-vinylimidazole, or VPC 55 K 65 W, vinylpyrrolidone-vinylcaprolactam, commercially available under the trademark Luvitec.

In one aspect, some segments of the capping agent may be adsorbed to the nanoparticle surface in an irregular manner. Other segments may extend away from the nanoparticle surface (e.g., on the order of 10-30 nm away from the surface). These extended segments may interact with segments adsorbed on adjacent nanoparticles, or, if the density of the capping agent adsorbed on the surfaces is low, touch and adsorb onto free surface space on an adjacent nanoparticle. This linking can undesirably lead to a net attraction between adjacent nanoparticles and thus cause agglomeration. For this reason, the capping agent preferably uniformly surrounds the nanoparticles to inhibit agglomeration. An important aspect for controlling the uniformity of the capping agent on the nanoparticle surface is the ratio of metallic nanoparticles to capping agent provided.

The weight ratio of metals (or alloys) in the metallic nanoparticles to the capping agent(s) carried thereon can vary over a wide range. The most advantageous ratio depends, inter alia, on factors such as the nature of the capping agent (polymer, low molecular weight substance, etc.) and the size of the metal cores of the nanoparticles (the smaller the size the higher the total surface area thereof and the higher the amount of capping agent that will desirably be present). Usually, the weight ratio will be not higher than about 100:1, e.g., not higher than about 50:1, or not higher than about 30:1. On the other hand, the weight ratio will usually be not lower than about 5:1, e.g., not lower than about 10:1, not lower than about 15:1, or not lower than about 20:1.

Metallic nanoparticles suitable for use in the present invention can be produced by a number of methods. A non-limiting example of such a method, commonly known as the polyol process, is disclosed in U.S. Pat. No. 4,539,041. A modification of this method is described in, e.g., P.-Y. Silvert et al., “Preparation of colloidal silver dispersions by the polyol process” Part 1—Synthesis and characterization, J. Mater. Chem., 1996, 6(4), 573-577; Part 2—Mechanism of particle formation, J. Mater. Chem., 1997, 7(2), 293-299. The entire disclosures of these documents are expressly incorporated by reference herein. Briefly, in the polyol process a metal compound is dissolved in, and reduced by a polyol such as, e.g., a glycol at elevated temperature to afford corresponding metal particles. In the modified polyol process the reduction is carried out in the presence of a dissolved polymer, i.e., polyvinylpyrrolidone.

A particularly preferred modification of the polyol process for producing metallic nanoparticles which carry a capping agent such as polyvinylpyrrolidone thereon is described in co-pending U.S. Provisional Application Ser. No. 60/643,378 entitled “Production of Metal Nanoparticles,” and in co-pending U.S. Provisional Application Ser. No. 60/643,629 entitled “Separation of Metal Nanoparticles,” both filed on Jan. 14, 2005. The entire disclosures of these co-pending applications are expressly incorporated by reference herein. In a preferred aspect of this modified process, a dissolved metal compound (e.g., a silver compound such as silver nitrate) is combined with and reduced by a polyol (e.g., ethylene glycol, propylene glycol and the like) at an elevated temperature (e.g., at about 120° C.) and in the presence of a heteroatom containing polymer (e.g., polyvinylpyrrolidone) which serves as the capping agent.

According to a preferred aspect of the present invention, the metallic nanoparticles exhibit a narrow particle size distribution. A narrow particle size distribution is particularly advantageous for direct-write applications because it results in a reduced clogging of the orifice of a direct-write device by large particles and provides the ability to form features having a fine line width, high resolution and acceptable packing density.

The metallic nanoparticles for use in the present invention preferably also show a high degree of uniformity in shape. Preferably, the metallic nanoparticles are substantially spherical in shape. Spherical particles are particularly advantageous because they are able to disperse more readily in a liquid suspension and impart advantageous flow characteristics to the metallic ink, particularly for deposition using an ink-jet device or similar tool. For a given level of solids loading, a low viscosity metallic ink having spherical particles will have a lower viscosity than a composition having non-spherical particles, such as flakes. Spherical particles are also less abrasive than jagged or plate-like particles, reducing the amount of abrasion and wear on the deposition tool.

In a preferred aspect of the present invention, at least about 90%, e.g., at least about 95%, or at least about 99% of the metallic nanoparticles comprised in the inks are substantially spherical in shape. In another preferred aspect, the metallic inks are substantially free of particles in the form of flakes.

In yet another preferred aspect, the particles are substantially free of micron-size particles, i.e., particles having a size of about 1 micron or above. Even more preferably, the nanoparticles may be substantially free of particles having a size (=largest dimension, e.g., diameter in the case of substantially spherical particles) of more than about 500 nm, e.g., of more than about 200 nm, or of more than about 100 nm. In this regard, it is to be understood that whenever the size and/or dimensions of the metallic nanoparticles are referred to herein and in the appended claims, this size and these dimensions refer to the nanoparticles without capping agent thereon, e.g., the metal cores of the nanoparticles. Depending on the type and amount of capping agent, an entire nanoparticle, e.g., a nanoparticle which has the capping agent thereon, may be significantly larger than the metal core thereof. Also, the term “nanoparticle” as used herein and in the appended claims encompasses particles having a size/largest dimension of the metal cores thereof of up to about 900 nm, preferably of up to about 500 nm, more preferably up to about 200 nm, or up to about 100 nm.

By way of non-limiting example, not more than about 5%, e.g., not more than about 2%, not more than about 1%, or not more than about 0.5% of the metallic nanoparticles may be particles whose largest dimension (and/or diameter) is larger than about 200 nm, e.g., larger than about 150 nm, or larger than about 100 nm. In a particularly preferred aspect, at least about 90%, e.g., at least about 95%, of the metallic nanoparticles will have a size of not larger than about 80 nm and/or at least about 80% of the metallic nanoparticles will have a size of from about 20 nm to about 70 nm. For example, at least about 90%, e.g., at least about 95% of the nanoparticles may have a size of from about 30 nm to about 50 nm.

In another aspect, the metallic nanoparticles may have an average particle size (number average) of at least about 10 nm, e.g., at least about 20 nm, or at least about 30 nm, but preferably not higher than about 80 nm, e.g., not higher than about 70 nm, not higher than about 60 nm, or not higher than about 50 nm. For example, the metallic nanoparticles may have an average particle size in the range of from about 25 nm to about 75 nm.

In yet another aspect of the present invention, at least about 80 volume percent, e.g., at least about 90 volume percent of the metallic nanoparticles may be not larger than about 2 times, e.g., not larger than about 1.5 times the average particle size (volume average).

As indicated above, nanoparticles may form agglomerates as a result of their relatively high surface energies, as compared to larger particles. Even in the presence of the capping agent, the inks may contain a minor amount of agglomerates in the form of soft agglomerates, particularly after storage for extended periods of time. However, it is known that such soft agglomerates may be dispersed easily by treatments such as exposure to ultrasound in a liquid medium, sieving, high shear mixing and 3-roll milling.

The average particle sizes and particle size distributions described herein may be measured by mixing samples of the powders in a liquid medium and exposing the resultant suspension to ultrasound through either an ultrasonic bath or horn. The ultrasonic treatment supplies sufficient energy to disperse the soft agglomerates into primary particles. The primary particle size and size distribution may then be measured by, e.g., SEM or TEM. Thus, the references to particle size herein refer to the primary particle size, such as after lightly dispersing soft agglomerates of the particles.

The nanoparticles that are useful in metallic inks according to the present invention preferably have a high degree of purity. For example, the particles (without capping agent) may include not more than about 1 atomic percent impurities, e.g., not more than about 0.1 atomic percent impurities, preferably not more than about 0.01 atomic percent impurities. Impurities are those materials that are not intended in the final product (e.g., the electrical conductor) and that adversely affect the properties of the final product. For many electronic applications, the most critical impurities to avoid are Na, K, Cl, S and F.

The metallic nanoparticles carrying a capping agent thereon for use in the present invention may, of course, also be produced by processes which are different from the (modified) polyol process referred to above. By way of non-limiting example, particles coated with a capping agent may be produced by a spray pyrolysis process. One or more coating precursors can vaporize and fuse to the hot nanoparticle surface and thermally react resulting in the formation of a thin film coating by chemical vapor deposition (CVD). Preferred coatings deposited by CVD include metal oxides. Further, the coating can be formed by physical vapor deposition (PVD) wherein a coating material physically deposits on the surface of the particles. Preferred coatings deposited by PVD include organic materials. Alternatively, a gaseous coating precursor can react in the gas phase forming small particles, for example, less than about 5 nanometers in size, which then diffuse to the larger metallic nanoparticle surface and sinter onto the surface, thus forming a coating. This method is referred to as gas-to-particle conversion (GPC). Another possible surface coating method is surface conversion of the particles by reaction with a vapor phase reactant to convert the surface of the nanoparticles to a different material than that originally contained in the particles.

In another aspect, the metallic nanoparticles can be coated with an intrinsically conductive polymer (which at the same time may serve as a capping agent), preventing or inhibiting agglomeration in the ink and providing a conductive path after solidification of the composition.

It is preferred for the total loading of metallic nanoparticles in the inks be not higher than about 75% by weight, such as from about 5% by weight to about 60% by weight, based on the total weight of the ink. Loadings in excess of the preferred amounts can lead to undesirably high viscosities and/or undesirable flow characteristics. Of course, the maximum loading which still affords useful results also depends on the density of the metal. In other words, the higher the density of the metal of the nanoparticles, the higher will be the acceptable and desirable loading in weight percent. In preferred aspects, the nanoparticle loading is at least about 10% by weight, e.g., at least about 15% by weight, at least about 20% by weight, or at least about 40% by weight. Depending on the metal, the loading will often not be higher than about 65% by weight, e.g., not higher than about 60% by weight. These percentages refer to the total weight of the nanoparticles, i.e., including any capping agent carried (e.g., adsorbed) thereon.

2. Liquid Vehicle

As indicated above, the ink (or inks) used to form the electrical conductor of the present invention preferably includes a liquid vehicle, which imparts flowability to the ink, optionally in combination with one or more other compositions. The vehicle preferably comprises a liquid that is capable of stably dispersing the metallic nanoparticles carrying the capping agent thereon, e.g., are capable of affording a dispersion that can be kept at room temperature for several days or even one, two, three weeks or months or even longer without substantial agglomeration and/or settling of the metallic nanoparticles. To this end, it is preferred for the vehicle and/or individual components thereof to be compatible with the surface of the nanoparticles, e.g., to be capable of interacting (e.g., electronically and/or sterically and/or by hydrogen bonding and/or dipole-dipole interaction, etc.) with the surface of the nanoparticles and in particular, with the capping agent.

It is particularly preferred for the vehicle to be capable of dissolving the capping agent to at least some extent, for example, in an amount (at 20° C.) of at least about 5 g of capping agent per liter of vehicle, particularly in an amount of at least about 10 g of capping agent, e.g., at least about 15 g, or at least about 20 g per liter of vehicle, preferably in an amount of at least about 100 g, or at least about 200 g per liter of vehicle. In this regard, it is to be appreciated that these preferred solubility values are merely a measure of the compatibility between the vehicle and the capping agent. They are not to be construed as indications that, in the inks, the vehicle is intended to actually dissolve the capping agent and remove it from the surface of the nanoparticles.

In view of the preferred interaction between the vehicle and/or individual components thereof and the capping agent on the surface of the nanoparticles, the most advantageous vehicle and/or component thereof for the ink(s) is largely a function of the nature of the capping agent. For example, a capping agent which comprises one or more polar groups such as, e.g., a polymer like polyvinylpyrrolidone will advantageously be combined with a vehicle which comprises (or predominantly consists of) one or more polar components (solvents) such as, e.g., a protic solvent, whereas a capping agent which substantially lacks polar groups will preferably be combined with a vehicle which comprises, at least predominantly, aprotic, non-polar components.

Particularly if the ink(s) are intended for use in direct-write applications such as, e.g., ink-jet printing, the vehicle is preferably selected to also satisfy the requirements imposed by the direct-write method and tool such as, e.g., an ink-jet head, particularly in terms of viscosity and surface tension of the ink(s). These requirements are discussed in more detail further below. Another consideration in this regard is the compatibility of the nanoparticle composition with the substrate in terms of, e.g., wetting behavior (contact angle with the substrate).

In a preferred aspect, the vehicle in the ink(s) may comprise a mixture of at least two solvents, preferably at least two organic solvents, e.g., a mixture of at least three organic solvents, or at least four organic solvents. The use of more than one solvent is preferred because it allows, inter alia, to adjust various properties of a composition simultaneously (e.g., viscosity, surface tension, contact angle with intended substrate etc.) and to bring all of these properties as close to the optimum values as possible.

The solvents comprised in the vehicle may be polar or non-polar or a mixture of both, mainly depending on the nature of the capping agent. The solvents should preferably be miscible with each other to a significant extent. Non-limiting examples of solvents that are useful for the purposes of the present invention include alcohols, polyols, amines, amides, esters, acids, ketones, ethers, water, saturated hydrocarbons, and unsaturated hydrocarbons.

Particularly in the case of a capping agent which comprises one or more heteroatoms which are available for hydrogen bonding, ionic interactions, etc. (such as, e.g., O and N), it is advantageous for the vehicle in the ink(s) to comprise one or more polar solvents and, in particular, protic solvents. For example, the vehicle may comprise a mixture of at least two protic solvents, or at least three protic solvents. Non-limiting examples of such protic solvents include alcohols (e.g., aliphatic and cycloaliphatic alcohols having from 1 to about 12 carbon atoms such as, e.g., methanol, ethanol, n-propanol, isopropanol, 1-butanol, 2-butanol, sek.-butanol, tert.-butanol, the pentanols, the hexanols, the octanols, the decanols, the dodecanols, cyclopentanol, cyclohexanol, and the like), polyols (e.g., alkanepolyols having from 2 to about 12 carbon atoms and from 2 to about 4 hydroxy groups such as, e.g., ethylene glycol, propylene glycol, butylene glycol, 1,3-propanediol, 1,3-butanediol, 1,4-butanediol, 2-methyl-2,4-pentanediol, glycerol, trimethylolpropane, pentaerythritol, and the like), polyalkylene glycols (e.g., polyalkylene glycols comprising from about 2 to about 5 C₂₋₄ alkylene glycol units such as, e.g., diethylene glycol, triethylene glycol, tetraethylene glycol, dipropylene gycol, tripropylene glycol and the like) and partial ethers and esters of polyols and polyalkylene glycols (e.g., mono(C₁₋₆ alkyl) ethers and monoesters of the polyols and polyalkylene glycols with C₁₋₆ alkanecarboxylic acids, such as, e.g., ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether and diethylene glycol monobutyl ether (DEGBE), ethylene gycol monoacetate, diethylene glycol monoacetate, and the like).

In one aspect, the liquid vehicle in the ink(s) comprises at least two solvents, e.g., at least three solvents, which solvents are preferably selected from C₂₋₄ alkanols, C₂₋₄ alkanediols and glycerol. For example, the vehicle may comprise ethanol, ethylene glycol and glycerol such as, e.g., from about 35% to about 45% by weight of ethylene glycol, from about 30% to about 0.40% by weight of ethanol and from about 20% to about 30% by weight of glycerol, based on the total weight of the vehicle. In a preferred aspect, the vehicle comprises about 40% by weight of ethylene glycol, about 35% by weight of ethanol and about 25% by weight of glycerol.

In another aspect, the liquid vehicle comprises a C₁₋₄ monoalkyl ether of a C₂₋₄ alkanediol and/or of a polyalkylene glycol.

In yet another aspect, the vehicle comprises not more than about 5 weight percent of water, e.g., not more than about 2 weight percent, or not more than about 1 weight percent of water, based on the total weight of the vehicle. For example, the vehicle may be substantially anhydrous.

Further non-limiting examples of organic solvents that may advantageously be used as the vehicle or a component thereof, respectively, include N,N-dimethylformamide, N,N-dimethylacetamide, ethanolamine, diethanolamine, triethanolamine, trihydroxymethylaminomethane, 2-(isopropylamino)-ethanol, 2-pyrrolidone, N-methylpyrrolidone, acetonitrile, the terpineols, ethylene diamine, benzyl alcohol, isodecanol, nitrobenzene and nitrotoluene.

As discussed in more detail below, when selecting a solvent combination for the liquid vehicle, it is desirable to also take into account the requirements, if any, imposed by the deposition tool (e.g., in terms of viscosity and surface tension of the ink) and the surface characteristics (e.g., hydrophilic or hydrophobic) of the intended substrate. In preferred inks, particularly those intended for ink-jet printing with a piezo head, the preferred viscosity thereof (measured at 20° C.) is not lower than about 5 cP, e.g., not lower than about 8 cP, or not lower than about 10 cP, and not higher than about 30 cP, e.g., not higher than about 20 cP, or not higher than about 15 cP. Preferably, the viscosity shows only small temperature dependence in the range of from about 20° C. to about 40° C., e.g., a temperature dependence of not more than about 0.4 cP/° C. It has surprisingly been found that in the case of preferred use in the present invention the presence of metallic nanoparticles vehicles does not significantly change the viscosity of the vehicle, at least at relatively low loadings such as, e.g., up to about 20 weight percent. This may in part be due to the usually large difference in density between the vehicle and the nanoparticles which manifests itself in a much lower number of particles than the number of particles that the mere weight percentage thereof would suggest.

Further, the above preferred inks exhibit preferred surface tensions (measured at 20° C.) of not lower than about 20 dynes/cm, e.g., not lower than about 25 dynes/cm, or not lower than about 30 dynes/cm, and not higher than about 40 dynes/cm, e.g., not higher than about 35 dynes/cm.

3. Additives

The inks used to form the electrical conductors of the present invention also may include one or more additives. Non-limiting examples of such additives will be discussed below. It should be taken into account that additives will in many cases have an adverse effect on the conductivity of the final material, in particular, if they can be removed from the material only with difficulty (e.g., by decomposition with the application of high temperatures) or not at all. Therefore it will usually be desirable to keep the amount of conductivity-impairing additives at a minimum.

The ink optionally includes an adhesion promoter for improving the adhesion of the metal (e.g., electrical conductor) to the underlying substrate. It has been found that electrical conductors made from the inks described herein show a satisfactory to excellent adhesion to various substrates without the presence of adhesion promoters. For example, in the case of preferred inks such as those which comprise metallic nanoparticles and in particular, silver nanoparticles and polyvinylpyrrolidone as capping agent, it has been found that the capping agent itself may act as adhesion promoter, especially in the case of polymeric substrates. Further, the adhesive strength may be dependent, inter alia, on the processing temperature of the deposited ink(s). Particularly, even in the absence of separately added adhesion promoter the preferred inks of the present invention have been found to exhibit very good adhesion to FR4 (glass fibers impregnated with epoxy resin) substrates when processed (cured) in the temperature range of from about 100° C. to about 180° C., satisfactory to very good adhesion to Mylar® substrates in the temperature range of from about 100° C. to about 180° C., satisfactory adhesion to Kapton® substrates at temperatures of about 200° C. and higher, and to glass substrates at temperatures of about 350° C. and higher. Good to excellent adhesion to ITO substrates has been observed at temperatures of about 350° C. and higher.

Especially in the case of glass surfaces, the adhesion of silver-containing inks can be (significantly) improved by the addition of an adhesion promoter. Non-limiting examples of adhesion promoters that may be included in the ink(s) (with silver and other metals which would benefit from the use of an adhesion promoter) include metals as well as metal compounds which are oxides or can be converted to oxides by thermal decomposition, oxidation in an oxygen containing atmosphere, etc. Non-limiting examples of metals for the adhesion promoter include B, Si, Pb, Cu, Zn, Ni and Bi. Especially in the case of a glass substrate, a low melting point glass is yet another example of a suitable adhesion promoter. A specific example of a preferred adhesion promoter is bismuth nitrate (which decomposes to form bismuth oxide at a temperature of about 260° C.). By way of non-limiting example, an atomic ratio Ag:Bi in the range of from about 15:1 to about 7:1 may be particularly advantageous. The addition of bismuth nitrate results in a consistently good adhesion of deposited silver to glass surfaces over the entire tested temperature range of from about 100° C. to about 550° C.

In the case of, e.g., nickel-containing inks, on the other hand, the adhesion to glass substrates is good even without the presence of an adhesion promoter. This may be due to the formation of nickel oxide during the thermal processing of a deposited nickel nanoparticle composition of the present invention.

Of course, in addition to bismuth nitrate and the other adhesion promoters mentioned above, there is a variety of other adhesion promoters that can afford desirable results when included in the ink(s). The effectiveness of a given adhesion promoter will usually depend, inter alia, on the metal of the nanoparticle, the substrate, the processing temperature, etc. The adhesion promoter is preferable soluble in the liquid vehicle, but may also be present in the form of, e.g., ultrafine particles that are dispersed in the liquid vehicle. In other words, adhesion promoters can be added to the ink in particulate form (e.g., in the case Ni in the form of nickel nanoparticles). Further non-limiting examples of adhesion promoters for use in the present invention are disclosed in, e.g., U.S. Pat. No. 5,750,194, the entire disclosure whereof is incorporated by reference herein in its entirety. Furthermore, polymers such as, e.g., polyamic acid, acrylics and styrene acrylics can improve the adhesion of a metal to a polymer substrate, as can substances such as coupling agents, e.g., titanates and silanes.

An adhesion promoter can also be added to the ink in the form of a metal precursor to a metal (e.g., a chemical precursor to a metal) such as, e.g., in the form of a metal salt (e.g., a carboxylate or nitrate), a metal alkoxide, etc. Adhesion promoters can also be applied to the substrate prior to printing of a nanoparticle ink, preferably by the same printing method but optionally also by an alternative method such as, e.g., spin coating or dip coating.

It also is to be noted that, in certain cases the polymer that serves the function of a capping agent for the nanoparticles of, e.g., an ink, may also provide improved structural integrity on a variety of substrates when curing is performed at relatively low temperatures (e.g., from about 75° C. to about 350° C.). At such low temperatures, the polymer (shell) will not volatilize, but rather rearrange while allowing the metal cores of the particles to touch and preferably sinter together. The polymer now can serve, in an increased manner, as an adhesion promoter between the metallic nanoparticles (or nodes formed therefrom) and the substrate. In addition, it may also provide additional cohesive strength between individual particles.

The inks used to form the electrical conductors can also include rheology modifiers. Non-limiting examples of rheology modifiers that are suitable for use in the present invention include SOLTHIX 250 (Avecia Limited), SOLSPERSE 21000 (Avecia Limited), styrene allyl alcohol (SAA), ethyl cellulose, carboxy methylcellulose, nitrocellulose, polyalkylene carbonates, ethyl nitrocellulose, and the like. These additives can reduce spreading of the inks after deposition, as discussed in more detail below.

The ink or inks optionally further include additives such as, e.g., wetting angle modifiers, humectants, crystallization inhibitors and the like. Of particular interest are crystallization inhibitors as they prevent crystallization and the associated increase in surface roughness and film uniformity during curing at elevated temperatures and/or over extended periods of time.

Although the ink or inks may include one or more metal precursors as disclosed in, e.g., published U.S. Patent Application Nos. 2003/0148024 A1 and 2003/0180451 A1, the entire disclosures of which are expressly incorporated by reference herein, it is preferred that the ink(s) be substantially free of such metal precursor compounds.

Also, the inks preferably do not comprise added binder, e.g., polymeric binder. In this regard it is to be noted that, in the case of polymeric capping agents such as, e.g., polyvinylpyrrolidone, the capping agent itself may serve as a binder, as explained in more detail below.

A variety of surfactants, either anionic, nonionic, cationic or ampholytic, may also be incorporated in the ink to improve leveling properties of writings formed on impervious writing surfaces. Preferred surfactants include polyoxyethylene carboxylic acid, sulfonic acid, sulfate or phosphate nonionic or anionic surfactants, ampholytic betaine surfactants and fluorinated surfactants. The amount of surfactants optionally is not more than 10% by weight, preferably not more than 5% by weight, based on the total weight of the ink composition. The use of surfactants in excess amounts adversely affects the dispersibility of the resultant ink compositions.

B. Substrates

Preferred inks according to the present invention can be deposited and converted to electrical conductors at low temperatures, thereby enabling the use of a variety of substrates having a relatively low softening (melting) or decomposition temperature.

Non-limiting examples of substrates that are particularly advantageous according to the present invention include substrates comprising one or more of fluorinated polymer, polyimide, epoxy resin (including glass-filled epoxy resin), polycarbonate, polyester, polyethylene, polypropylene, polyvinyl chloride, ABS copolymer, synthetic paper, flexible fiberboard, non-woven polymeric fabric, cloth and other textiles. Other particularly advantageous substrates include cellulose-based materials such as wood or paper, and metallic foil and glass (e.g., thin glass). The substrate may be coated. Although the inks can be used particularly advantageously for temperature-sensitive substrates, it is to be appreciated that other substrates such as, e.g., metallic and ceramic substrates can also be used in accordance with the present invention.

Of particular interest for display applications are glass substrates and ITO coated glass substrates. Other glass coatings that the metal features may be printed on in flat panel display applications include semiconductors such as c-Si on glass, amorphous Si on glass, poly-Si on glass, and organic conductors and semiconductors printed on glass. The glass may also be substituted with, e.g., a flexible organic transparent substrate such as PET or PEN. The metal or alloy (e.g., Ag) may also be printed on top of a black layer or coated with a black layer to improve the contrast of a display device. Other substrates of particular interest include printed circuit board substrates such as FR4, textiles including woven and non-woven textiles.

Another substrate of particular interest is natural or synthetic paper, in particular, paper that has been coated with specific layers to enhance gloss and accelerate the infiltration of ink solvent or liquid vehicle. A preferred example of a glossy coating for ink-jet paper includes alumina nanoparticles such as fumed alumina in a binder. Also, a silver ink according to the present invention that is ink-jet printed on EPSON glossy photo paper and heated for about 30 min. at about 100° C. is capable of exhibiting highly conductive Ag metal lines with a bulk conductivity in the 10 micro-Ωcm range.

According to a preferred aspect of the present invention, the substrate onto which the metallic ink is deposited may have a softening and/or decomposition temperature of not higher than about 225° C., e.g., not higher than about 200° C., not higher than about 185° C., not higher than about 150° C., or not higher than about 125° C.

C. Deposition of Fine Features

A difficulty that may be encountered in the printing and processing of low viscosity metallic inks is that the inks can wet the surface and rapidly spread to increase the width of the deposit, thereby negating the advantages of fine line printing. This is particularly true when ink-jet printing is employed to deposit fine features such as interconnects, because ink-jet technology puts relatively strict upper boundaries on the viscosity of the inks that can be employed. Nonetheless, ink-jet printing is a preferred low-cost, large-area deposition technology that can be used to deposit the metallic inks of the present invention. It has surprisingly been found that the preferred inks and in particular, inks comprising silver nanoparticles carrying thereon polyvinylpyrrolidone as capping agent in a vehicle which comprises a mixture of protic solvents such as, e.g., a mixture of ethylene glycol, ethanol and glycerol, can be deposited on a variety of substrates without any significant spreading, thereby enabling the production of very fine electrical conductors.

According to a preferred aspect of the present invention, the inks can be confined on the substrate, thereby enabling the formation of features having a small minimum feature size, the minimum feature size being the smallest dimension in the x-y axis, such as the width of a conductive line. The preferred inks can be confined to regions having a width of not greater than about 200 μm, preferably not greater than about 150 μm, e.g., not greater than about 100 μm, or not greater than about 50 μm, even without the use of any anti-spreading additives and/or without resorting to any measures such as those discussed below.

In some cases, it may, however, be advantageous to add small amounts of rheology modifiers such as styrene allyl alcohol (SAA) and other polymers to the inks to reduce spreading. Spreading can also be controlled by rapidly drying the inks during printing by irradiating the inks during deposition.

Spreading can also be controlled by the addition of a low decomposition temperature polymer in monomer form. The monomer can be polymerized during deposition by thermal or radiation (e.g., ultraviolet) means, providing a network structure to maintain line shape. The resultant polymer can then be either retained or removed during subsequent processing of the conductor.

Another method comprises patterning an otherwise non-wetting substrate with wetting enhancement agents that control the spreading and also yield increased adhesion. By way of non-limiting example, this may be achieved by functionalizing the substrate surface with functional groups such as, e.g., hydroxide or carboxylate groups.

The fabrication of features with feature widths of not greater than about 100 μm or features with a minimum feature size of not greater than about 100 μm from a low viscosity ink may require the confinement of the ink so that the ink does not spread over certain defined boundaries. Various methods can be used to confine the ink on a surface, including surface energy patterning by increasing or decreasing the hydrophobicity (surface energy) of the surface in selected regions corresponding to where it is desired to confine the metallic nanoparticles or eliminate the metallic nanoparticles. These methods can be classified as physical barrier, electrostatic barrier, magnetic barrier, surface energy difference, and process related methods such as increasing the metallic nanoparticle viscosity to reduce spreading, for example by freezing or drying the ink very rapidly once it strikes the surface.

In physical barrier approaches, a confining structure is formed that keeps the ink(s) from spreading. These confining structures may be trenches and cavities of various shapes and depths below a flat or curved surface which confine the flow of the metallic ink. Such trenches can be formed by chemical etching or by photochemical means. The physical structure confining the inks can also be formed by mechanical means including embossing a pattern into a softened surface or means of mechanical milling, grinding or scratching features. Trenches can also be formed thermally, for example by locally melting a low melting point coating such as a wax coating. Alternatively, retaining barriers and patches can be deposited to confine the flow of an ink within a certain region. For example, a photoresist layer can be spin coated on a polymer substrate. Photolithography can be used to form trenches and other patterns in the photoresist layer. These patterns can be used to retain the ink or inks that are deposited onto these preformed patterns. After drying, the photolithographic mask may or may not be removed with the appropriate solvents without removing the deposited metal. Retaining barriers can also be deposited with direct-write deposition approaches such as ink-jet printing or any other direct-write approach, as disclosed herein.

For example, a polymer trench can be ink-jet printed onto a flat substrate by depositing two parallel lines with narrow parallel spacing. An ink, as described above, can be printed between the two polymer lines to confine the ink. Another group of physical barriers includes printed lines or features with a certain level of porosity that can retain a low viscosity ink by capillary forces. The confinement layer may comprise particles applied by any of the techniques disclosed herein. The particles confine the ink that is deposited onto the particles to the spaces between the particles because of wetting of the particles by the metallic ink.

Surface energy patterning can be classified by how the patterning is formed, namely by mechanical, thermal, chemical or photochemical means. In mechanical methods, the physical structure confining the ink is formed by mechanical means including embossing a pattern into a softened surface, milling features, or building up features to confine the ink. In thermal methods, heating of the substrate is used to change the surface energy of the surface, either across the entire surface or in selected locations, such as by using a laser or thermal print head. In chemical methods, the entire surface or portions of the surface are chemically modified by reaction with some other species. In one aspect, the chemical reaction is driven by local laser heating with either a continuous wave or pulsed laser. In photochemical methods, light from either a conventional source or from a laser is used to drive photochemical reactions that result in changes in surface energy.

The methods of confining the inks disclosed herein can involve two steps in series—first the formation of a confining pattern, that may be a physical or chemical confinement method, and second, the application of an ink or inks to the desired confinement areas.

Offset printing or lithographic printing can be used to print high resolution patterns that correspond to at least two levels of surface energies. In one aspect, the printing is carried out on a hydrophobic surface and a hydrophilic material is printed. The regions where no printing occurs correspond to hydrophobic material. A hydrophobic metallic ink can then be printed onto the hydrophobic regions thereby confining the ink. Alternatively, a hydrophilic nanoparticle ink can be printed onto the hydrophilic electrostatically printed regions. The width of the hydrophobic and hydrophilic regions may be not greater than about 100 μm, e.g., not greater than about 75 μm, not greater than about 50 μm, or not greater than about 25 μm.

The ink confinement may be accomplished by applying a photoresist and then laser patterning the photoresist and removing portions of the photoresist. The confinement may be accomplished by a polymeric resist that has been applied by another jetting technique or by any other technique resulting in a patterned polymer. In one aspect, the polymeric resist is hydrophobic and the substrate surface is hydrophilic. In that case, the ink utilized is hydrophilic resulting in confinement of the ink in the portions of the substrate that are not covered by the polymeric resist.

A laser can be used in various ways to modify the surface energy of a substrate in a patterned manner. The laser can be used, for example, to remove hydroxyl groups through local heating. These regions are converted to more hydrophobic regions that can be used to confine a hydrophobic or hydrophilic ink. The laser may also be used to remove selectively a previously applied surface layer formed by chemical reaction of the surface with a silanating agent.

In one aspect, a surface is laser processed to increase the hydrophilicity in regions where the laser strikes the surface. A polyimide substrate is coated with a thin layer of hydrophobic material, such as a fluorinated polymer. A laser, such as a pulsed YAG, excimer or other UV or shorter wavelength pulsed laser, can be used to remove the hydrophobic surface layer exposing the hydrophilic layer underneath. Translating (e.g., on an x-y axis) the laser allows patterns of hydrophilic material to be formed. Subsequent application of a hydrophilic ink to the hydrophilic regions allows confinement of the ink. Alternatively, a hydrophobic ink can be used and applied to the hydrophobic regions resulting in ink confinement.

In another aspect, a surface is laser processed to increase the hydrophobicity in regions where the laser strikes the surface. A hydrophobic substrate such as a fluorinated polymer can be chemically modified to form a hydrophilic layer on its surface. Suitable modifying chemicals include solutions of sodium naphthalenide. Suitable substrates include polytetrafluoroethylene and other fluorinated polymers. The dark hydrophilic material formed by exposing the polymer to the solution can be removed in selected regions by using a laser. Continuous wave and pulsed lasers can be used. Hydrophilic inks, for example aqueous based inks, can be applied to the remaining dark material. Alternatively, hydrophobic inks, such as those based on solutions in non-polar solvents, can be applied to the regions where the dark material was removed leaving the hydrophobic material underneath. Ceramic surfaces can be hydroxylated by heating in moist air or otherwise exposing the surface to moisture. The hydroxylated surfaces can be silanated to create a monolayer of hydrophobic molecules. The laser can be used to selectively remove the hydrophobic surface layer exposing the hydrophilic material underneath. A hydrophobic patterned layer can be formed directly by micro-contact printing using a stamp to apply a material that reacts with the surface to leave exposed a hydrophobic material such as, e.g., an aliphatic hydrocarbon chain. The ink or inks can be applied directly to the hydrophilic regions or hydrophobic regions using a hydrophilic or hydrophobic metallic ink, respectively.

A surface with patterned regions of hydrophobic and hydrophilic regions can be formed by micro-contact printing. In this approach, a stamp is used to apply a reagent to selected regions of a surface. This reagent can form a self-assembled monolayer that provides a hydrophobic surface. The regions between the hydrophobic surface regions can be used to confine hydrophilic inks. In a related approach, a surface having patterned regions of hydrophobic and hydrophilic regions can also be formed by liquid embossing. In this approach an elastomeric stamp comprising protrusions may be used to remove an agent, which had been previously applied to the surface, e.g., by spin coating or dip coating.

Ink modification can also be employed to confine the ink(s) on the substrate. Such methods restrict spreading of the inks by methods other than substrate modification. An ink that includes a binder can be used for surface confinement. By way of non-limiting example, the binder can be chosen such that it is a solid at room temperature, but is a liquid suitable for ink-jet deposition at higher temperatures. These inks are suitable for deposition through, for example, a heated ink-jet head.

Binders can also be used in the inks to provide mechanical cohesion and limit spreading of the ink after deposition, especially in non-electric and non-electronic applications. By way of non-limiting example, the binder may be a solid at room temperature. During ink-jet printing, the binder is heated and becomes flowable. In one aspect, the binder is a solid at room temperature, when heated to greater than about 50° C. the binder melts and flows allowing for ease of transfer and good wetting of the substrate, then upon cooling to room temperature the binder becomes solid again maintaining the shape of the deposited pattern. The binder can also react in some instances. Preferred binders include waxes, polymers such as, e.g., styrene allyl alcohols, polyalkylene carbonates and polyvinyl acetals, cellulose based materials, tetradecanol, trimethylolpropane and tetramethylbenzene. The preferred binders have good solubility in the vehicle used in the metallic ink and should be processable in the melt form. For example, styrene allyl alcohol is soluble in dimethylacetamide, solid at room temperature and becomes fluid-like upon heating to about 80° C.

The binder in many cases should depart out of the ink-jet printed feature or decompose cleanly during thermal processing, leaving little or no residuals after processing the metallic ink. The departure or decomposition can include vaporization, sublimation, unzipping, partial polymer chain breaking, combustion, or other chemical reactions induced by a reactant present on the substrate material, or deposited on top of the material.

In a preferred aspect of the present invention, the capping agent will also serve the function of a binder. A non-limiting example of such a capping agent/binder is a polymer such as polyvinylpyrrolidone. For example, upon heating the deposited ink, the polymer may become mobile and form a polymeric matrix or the like in which the metallic nanoparticles are embedded.

Other methods for controlling the spreading during printing of a low viscosity metallic ink according to the present invention include depositing a metallic ink onto a cooled substrate, freezing the ink as the droplets contact the substrate, removing at least the solvent without melting the ink, and converting the remaining components of the composition to the desired structure or material. The melting point of the ink is preferably less than about 25° C. Preferred solvents include higher molecular weight alcohols. It is preferred to cool the substrate to less than about 10° C.

Yet another method for controlling the spreading during printing according to the present invention comprises the steps of depositing an ink onto a porous substrate, thereby limiting the spreading of the ink, and converting the ink to a desired structure, e.g., a electrical conductor. In one aspect, the porosity in the substrate is created by laser patterning. The porosity can be limited to the very surface of the substrate.

Yet another method for controlling the spreading of a low viscosity inks according to the present invention includes the steps of patterning the substrate to form regions with two distinct levels of porosity where the porous regions form the pattern of a desired structure. The metallic ink(s) can then be deposited, such as by ink-jet printing, onto the regions defining the pattern thereby confining the metallic ink(s) to these regions, and converting the deposited ink(s) to a desired structure, e.g., an electrical conductor. Preferred substrates are polyimide, and epoxy laminates. In one aspect the patterning may be carried out with a laser. In another aspect the patterning may be carried out using photolithography. In another aspect, capillary forces pull at least some portion of the ink into the porous substrate.

Spreading of the metallic inks is influenced by a number of factors. A drop of liquid placed onto a surface will either spread or not depending on the surface tension of the liquid, the surface tension of the solid and the interfacial tension between the solid and the liquid. If the contact angle is greater than 90 degrees, the liquid is considered non-wetting and the liquid tends to bead or shrink away from the surface. For contact angles less than 90 degrees, the liquid can spread on the surface. For the liquid to completely wet, the contact angle must be zero. For spreading to occur, the surface tension of the liquid must be lower than the surface tension of the solid on which it resides.

In one aspect of the present invention, a metallic ink may be applied, e.g., by ink-jet deposition, to an unpatterned substrate. Unpatterned refers to the fact that the surface energy (surface tension) of the substrate has not been intentionally patterned for the sole purpose of confining the ink. It is to be understood that variations in surface energy (used synonymously herein with surface tension) of the substrate associated with devices, interconnects, vias, resists and any other functional features may already be present. For substrates with surface tensions of less than about 30 dynes/cm, a hydrophilic metallic ink may be based on ethanol, glycerol, ethylene glycol, and other solvents or liquids having surface tensions of greater than about 30 dynes/cm, more preferably greater than about 40 dynes/cm and preferably greater than about 50 dynes/cm and even greater than about 60 dynes/cm. For substrates with surface tensions of less than about 40 dynes/cm, the solvents should have surface tensions of greater than about 40 dynes/cm, preferably greater than about 50 dynes/cm and even more preferably greater than about 60 dynes/cm. For substrates with surface tensions of less than about 50 dynes/cm, the surface tension of the metallic ink should be greater than about 50 dynes/cm, preferably greater than about 60 dynes/cm. Alternatively, the surface tension of the ink can for example be chosen to be at least about 5 dynes/cm, at least about 10 dynes/cm, at least about 15 dynes/cm, at least about 20 dynes/cm, or at least about 25 dynes/cm greater than that of the substrate. Continuous ink-jet heads often require surface tensions of about 40 to about 50 dynes/cm. Bubble-jet ink-jet heads often require surface tensions of about 35 to about 45 dynes/cm. The previously described methods are particularly preferred for these types of deposition approaches.

In another aspect, a metallic ink may be applied, e.g., by ink-jet deposition, to an unpatterned low surface energy (hydrophobic) surface that has been surface modified to provide a high surface energy (hydrophilic). The surface energy can be increased by hydroxylating the surface by various means known to those of skill in the art including exposing to oxidizing agents and water, heating in moist air and the like. The surface tension of the metallic ink can then, for example, be chosen to be at least about 5, at least about 10, at least about 15, at least about 20, or at least about 25 dynes/cm lower than that of the substrate. Piezo-jet ink-jet heads operating with hot wax often require surface tensions of about 25 to about 30 dynes/cm. Piezo-jet ink-jet heads operating with UV curable inks often require surface tensions of about 25 to about 30 dynes/cm. Bubble-jet ink-jet heads operating with UV curable inks often require surface tensions of about 20 to about 30 dynes/cm. Surface tensions of roughly about 20 to about 30 dynes/cm are usually required for piezo-based ink-jet heads using solvents. The previously described methods are particularly preferred for these types of applications.

Most electronic substrates with practical applications have low values of surface tension, in the range of from about 18 (polytetrafluoroethylene) to about 45 dynes/cm, often from about 20 to about 40 dynes/cm. In one approach of confining a metallic ink to a narrow line or other shape, a hydrophilic pattern corresponding to the pattern of the desired conductor feature may be formed on the surface of a substrate through the methods discussed herein. A particularly preferred method uses a laser. For example, a laser can be used to remove a hydrophobic surface layer exposing a hydrophilic layer underneath. In one aspect, the hydrophilic material pattern on the surface has a surface energy that is at least about 5, at least about 10, at least about 15, at least about 20, at least about 25, or at least about 30 dynes/cm greater than that of the surrounding substrate. In another aspect, the surface tension of the ink is chosen to be lower than the surface tension of the hydrophilic region but higher than the surface tension of the hydrophobic region. The surface tension of the ink can, for example, be chosen to be at least about 5, at least about 10, at least about 15, at least about 20 or at least about 25 dynes/cm smaller than that of the hydrophilic regions. The surface tension of the ink can be chosen to be about 5, about 10, about 15, about 20, or about 25 dynes/cm higher than that of the hydrophobic regions. In another approach, the surface energy of the ink is higher than the surface energy of both the hydrophobic and hydrophilic regions. The surface tension of the ink may, for example, be chosen to be at least about 5, at least about 10, at least about 15, at least about 20, or at least about 25 dynes/cm higher than that of the hydrophilic regions. The surface tension of the ink may, for example, be chosen to be at least about 5, at least about 10, at least about 15, at least about 20, or at least about 25 dynes/cm smaller than that of the hydrophilic regions. This approach is preferred for aqueous-based metallic inks and compositions with high surface tensions in general. Continuous ink-jet heads often require surface tensions of from about 40 to about 50 dynes/cm. Bubble-jet ink-jet heads often require surface tensions of from about 35 to about 45 dynes/cm. The previously described methods are particularly preferred for these types of applications that can handle inks with high surface tensions.

In another approach to confining a metallic ink to a narrow feature, a hydrophilic surface, or a hydrophobic surface that is rendered hydrophilic by surface modification, may be patterned with a hydrophobic pattern. In one aspect, the hydrophobic pattern may, for example, have a surface energy that is at least about 5, at least about 10, at least about 15, at least about 20, at least about 25 or at least about 30 dynes/cm smaller than that of the surrounding substrate. This can be done by removing a hydrophilic surface layer using a laser to expose a hydrophobic region underneath. A hydrophobic metallic ink may be applied to the hydrophobic surface regions to confine the metallic ink. In another aspect, the hydrophobic ink may, for example, have a surface energy that is at least about 5, at least about 10, at least about 15, at least about 20, at least about 25 or at least about 30 dynes/cm lower than that of the surrounding substrate. In another aspect, the hydrophobic ink may, for example, have a surface energy that is at least about 5, at least about 10, at least about 15, at least about 20, at least about 25 or at least about 30 dynes/cm higher than that of the surrounding substrate. In another aspect, the hydrophobic metallic ink may, for example, have a surface energy that is at least about 5, at least about 10, at least about 15, at least about 20, at least about 25 or at least about 30 dynes/cm lower than that of the hydrophobic surface pattern. In another aspect, the hydrophobic ink may, for example, have a surface energy that is at least about 5, at least about 10, at least about 15, at least about 20, at least about 25 or at least about 30 dynes/cm higher than that of the hydrophobic surface pattern. In another aspect, the surface tension of the ink may be smaller than that of the hydrophilic regions and greater than that of the hydrophobic regions. The hydrophilic surface may, for example, have a surface tension of greater than about 40, greater than about 50 or greater than about 60 dynes/cm. When the hydrophobic surface has a surface energy of greater than about 40 dynes/cm, it is preferred to use a metallic ink having a surface tension of less than about 40, even less than about 30 dynes/cm, or less than about 25 dynes/cm. When the hydrophobic surface has a surface energy of greater than about 50 dynes/cm, it is preferred to use an ink with a surface tension of less than about 50, preferably less than about 40, even less than about 30 dynes/cm, and more preferably less than about 25 dynes/cm. When the hydrophobic surface has a surface tension of greater than about 40 dynes/cm, it is preferred to use an ink with a surface tension of less than about 40, less than about 35, less than about 30 and even less than about 25 dynes/cm.

For ink-jet heads and other deposition techniques that require surface tensions greater than about 30 dynes/cm, a particularly preferred method for confining a metallic ink to a surface involves increasing the hydrophilicity of the surface to provide a surface tension greater than about 40, greater than about 45 or greater than about 50 dynes/cm and then providing a hydrophobic surface pattern with a surface tension that is lower than that of the surrounding surface. For example, the surface tension of the pattern may be at least about 5, at least about 10, at least about 15, at least about 20 or at least about 25 dynes/cm higher than the surface tension of the surrounding substrate.

Lateral ink migration of metallic inks also may be limited by use of an elastomeric material such as a polysiloxane. In this aspect, a coating of a thin film of an elastomeric material is applied onto a substrate. The elastomeric material optionally comprises a polysiloxane, e.g., a surface modified polydimethylsiloxane (PDMS). The metallic ink is then applied to the pre-coated substrate. In regions where the metallic ink contacts the elastomeric material, it is immediately arrested thereby inhibiting lateral spreading. The arresting is obtained by means of diffusion of the metallic ink liquid vehicle (e.g., solvent) into the thin layer of elastomeric material, causing an increase in viscosity of the resulting mixed composition. In an alternative approach, a flat elastomeric stamp can be brought into contact with the metallic ink after the metallic ink has been printed onto a substrate. In this case, the elastomeric stamp, which has an unmodified surface of an elastomeric material such as PDMS, is lowered on top of the printed feature, held for some amount of time to allow the liquid vehicle from the metallic ink to diffuse into the elastomeric material, and then removed leaving a mixed composition having increased viscosity relative the metallic ink that was initially applied to the substrate. This increased viscosity inhibits lateral spreading.

Surfactants, i.e., molecules with hydrophobic tails corresponding to lower surface tension and hydrophilic ends corresponding to higher surface tension may be used to modify the inks and substrates to achieve the required values of surface tensions and interfacial energies.

For the purposes of this application, hydrophobic means a material that repels water. Hydrophobic materials have low surface tensions. They also do not have functional groups for forming hydrogen bonds with water.

Hydrophilic means a material that has an affinity for water. Hydrophilic surfaces are wetted by water. Hydrophilic materials also have high values of surface tension. They can also form hydrogen bonds with water. The surface tensions for different liquids are listed in Table 2 and the surface energies for different solids are listed in Table 3.

TABLE 2
SURFACE TENSIONS OF VARIOUS LIQUIDS

| | | Surface |
|---|---|---|
| | Temp | Tension |
| Liquid | (° C.) | (dynes/cm) |
| Water | 20 | 72.75 |
| Acetamide | 85 | 39.3 |
| Acetone | 20 | 23.7 |
| Acetonitrile | 20 | 29.3 |
| n-Butanol | 20 | 24.6 |
| Ethanol | 20 | 24 |
| Hexane | 20 | 18.4 |
| Isopropanol | 20 | 22 |
| Glycerol | 20 | 63.4 |
| Ethylene | 20 | 47.7 |
| glycol | | |
| Tolulene | 20 | 29 |

TABLE 3
SURFACE ENERGIES OF VARIOUS SOLIDS

| | Surface |
|---|---|
| | Energy |
| Material | (dynes/cm) |
| Glass | 30 |
| PTFE | 18 |
| Polyethylene | 31 |
| Polyvinychloride | 41 |
| Polyvinylidene | 25 |
| fluoride | |
| Polypropylene | 29 |
| Polystyrene | 33 |
| Polyvinylchloride | 39 |
| Polysulfone | 41 |
| Polycarbonate | 42 |
| Polyethylene | 43 |
| terephthalate | |
| Polyacrylonitrile | 44 |
| Cellulose | 44 |

D. Deposition of Metallic Inks

The metallic inks can be deposited onto surfaces using a variety of tools such as, e.g., low viscosity deposition tools. As used herein, a low viscosity deposition tool is a device that deposits a liquid or liquid suspension onto a surface by ejecting the ink through an orifice toward the surface without the tool being in direct contact with the surface. The low viscosity deposition tool is preferably controllable over an x-y grid, referred to herein as a direct-write deposition tool. A preferred direct-write deposition tool according to the present invention is an ink-jet device. Other examples of direct-write deposition tools include aerosol jets and automated syringes, such as the MICROPEN tool, available from Ohmcraft, Inc., of Honeoye Falls, N.Y.

For ink-jet applications, the viscosity of the metallic ink preferably is not greater than about 50 cP, e.g., in the range of from about 10 to about 40 cP. For aerosol jet atomization applications, the viscosity is preferably not greater than about 20 cP. Automated syringes can use compositions having a higher viscosity, such as up to about 5000 cP.

A preferred direct-write deposition tool for the purposes of the present invention is an ink-jet device. Ink-jet devices operate by generating droplets of the composition and directing the droplets toward a surface. The position of the ink-jet head is carefully controlled and can be highly automated so that discrete patterns of the composition can be applied to the surface. Ink-jet printers are capable of printing at a rate of about 1000 drops per jet per second or higher and can print linear features with good resolution at a rate of about 10 cm/sec or more, up to about 1000 cm/sec. Each drop generated by the ink-jet head includes approximately 25 to about 100 picoliters of the composition, which is delivered to the surface. For these and other reasons, ink-jet devices are a highly desirable means for depositing materials onto a surface.

Typically, an ink-jet device includes an ink-jet head with one or more orifices having a diameter of not greater than about 100 μm, such as from about 50 μm to about 75 μm. Droplets are generated and are directed through the orifice toward the surface being printed. Ink-jet printers typically utilize a piezoelectric driven system to generate the droplets, although other variations are also used. Ink-jet devices are described in more detail in, for example, U.S. Pat. Nos. 4,627,875 and 5,329,293, the disclosures whereof are incorporated by reference herein in their entireties.

It is also expedient to simultaneously control the surface tension and the viscosity of the metallic ink to enable the use of industrial ink-jet devices. Preferably the surface tension is from about 10 to about 50 dynes/cm, such as from about 20 to about 40 dynes/cm, while the viscosity is maintained at a value of not greater than about 50 centipoise.

According to one aspect, the solids loading of particles in the metallic ink is preferably as high as possible without adversely affecting the viscosity or other desired properties of the composition. As set forth above, a metallic ink preferably has a particle loading of not higher than about 75 weight percent, e.g., from about 5 to about 50 weight percent.

Metallic inks intended for use in an ink-jet device may also include surfactants to maintain the particles in suspension. Co-solvents, also known as humectants, can be used to prevent the metallic ink from crusting and clogging the orifice of the ink-jet head. Biocides can also be added to prevent bacterial growth over time. Non-limiting examples of corresponding ink-jet liquid vehicle compositions are disclosed in, e.g., U.S. Pat. Nos. 5,853,470; 5,679,724; 5,725,647; 4,877,451; 5,837,045 and 5,837,041, the entire disclosures whereof are incorporated by reference herein. The selection of such additives is based upon the desired properties of the composition, as is known to those skilled in the art. As set forth above, if the composition is intended for the fabrication of conductors, care should be taken that the additives of the composition do not have a significant adverse effect on the conductivity of the final feature and/or can be removed easily.

The metallic inks can also be deposited by aerosol jet deposition. Aerosol jet deposition allows the formation of electrical conductors having a feature width of, e.g., not greater than about 200 μm, such as not greater than about 150 μm, not greater than about 100 μm and even not greater than about 50 μm. In aerosol jet deposition, the metallic ink is aerosolized into droplets and the droplets are transported to the substrate in a flow gas through a flow channel. Typically, the flow channel is straight and relatively short.

The aerosol can be created using a number of atomization techniques. Examples include ultrasonic atomization, two-fluid spray head, pressure atomizing nozzles and the like. Ultrasonic atomization is preferred for compositions with low viscosities and low surface tension. Two-fluid and pressure atomizers are preferred for higher viscosity fluids. Solvent or can be added to the metallic ink during atomization, if necessary, to keep the concentration of metallic nanoparticle components substantially constant during atomization.

The size of the aerosol droplets can vary depending on the atomization technique. In one aspect, the average droplet size is not greater than about 10 μm, e.g., not greater than about 5 μm. Large droplets can be optionally removed from the aerosol, such as by the use of an impactor.

Low aerosol concentrations require large volumes of flow gas and can be detrimental to the deposition of fine features. The concentration of the aerosol can optionally be increased, such as by using a virtual impactor. The concentration of the aerosol may be greater than about 10⁶ droplets/cm³, e.g., greater than about 10⁷ droplets/cm³. The concentration of the aerosol can be monitored and the information can be used to maintain the mist concentration within, for example, about 10% of the desired mist concentration over a period of time.

The droplets may be deposited onto the surface of the substrate by inertial impaction of larger droplets, electrostatic deposition of charged droplets, diffusional deposition of sub-micron droplets, interception onto non-planar surfaces and settling of droplets, such as those having a size in excess of about 10 μm.

Examples of tools and methods for the deposition of fluids using aerosol jet deposition include those disclosed in U.S. Pat. Nos. 6,251,488; 5,725,672 and 4,019,188, the entire disclosures whereof are incorporated by reference herein.

The metallic inks of the present invention can also be deposited by a variety of other techniques including, liquid embossing after spin coating the metallic ink, stamping, intaglio, roll printer, spraying, dip coating, spin coating, and other techniques that direct discrete units of fluid or continuous jets, or continuous sheets of fluid to a surface. Other examples of advantageous printing methods for the compositions of the present invention include lithographic printing and gravure printing. For example, gravure printing can be used with metallic inks having a viscosity of up to about 5,000 centipoise. The gravure method can deposit features having an average thickness of from about 1 μm to about 25 μm and can deposit such features at a high rate of speed, such as up to about 700 meters per minute. The gravure process also comprises the direct formation of patterns onto the surface.

Lithographic printing methods can also be utilized with the nanoparticle compositions of the present invention. In the lithographic process, the inked printing plate contacts and transfers a pattern to a rubber blanket and the rubber blanket contacts and transfers the pattern to the surface being printed. A plate cylinder first comes into contact with dampening rollers that transfer an aqueous solution to the hydrophilic non-image areas of the plate. A dampened plate then contacts an inking roller and accepts the ink only in the oleophilic image areas.

Using one or more of the foregoing deposition techniques, it is possible to deposit the metallic ink on one side or both sides of a substrate. Further, the processes can be repeated to deposit multiple layers of the same or different metallic inks on a substrate.

An optional first step may comprise a surface modification of the substrate as discussed above. The surface modification may be applied to the entire substrate or may be applied in the form of a pattern, such as by using photolithography. The surface modification may, for example, include increasing or decreasing the hydrophilicity of the substrate surface by chemical treatment. For example, a silanating agent can be used on the surface of a glass substrate to increase the adhesion and/or to control spreading of the metallic ink through modification of the surface tension and/or wetting angle. The surface modification may also include the use of a laser to clean the substrate. The surface may also be subjected to mechanical modification by contacting with another type of surface. The substrate may also be modified by corona treatment.

For example, a line of polyimide can be printed prior to deposition of a metallic ink, such as a silver metallic ink, to prevent infiltration of the composition into a porous substrate, such as paper. In another example, a primer material may be printed onto a substrate to locally etch or chemically modify the substrate, thereby inhibiting the spreading of the metallic ink being deposited in the following printing step. In yet another example, a via can be etched by printing a dot of a chemical that is known to etch the substrate. The via can then be filled in a subsequent printing process to connect circuits being printed on the front and back of the substrate.

As discussed above, the deposition of a metallic ink according to the present invention can be carried out, for example, by pen/syringe, continuous or drop on demand ink-jet, droplet deposition, spraying, flexographic printing, lithographic printing, gravure printing, other intaglio printing, and others. The metallic ink can also be deposited by dip-coating or spin-coating, or by pen dispensing onto rod or fiber type substrates. Immediately after deposition, the composition may spread, draw in upon itself, or form patterns depending on the surface modification discussed above. In another aspect, a method is provided for processing the deposited composition using two or more jets or other ink sources. An example of a method for processing the deposited composition is using infiltration into a porous bed formed by a previous fabrication method. Another exemplary method for depositing the composition is using multi-pass deposition to build the thickness of the deposit. Another example of a method for depositing the composition is using a heated head to decrease the viscosity of the composition.

The properties of the deposited metallic ink can also be subsequently modified. This can include freezing, melting and otherwise modifying the properties such as viscosity with or without chemical reactions or removal of material from the metallic ink. For example, a metallic ink including a UV-curable polymer can be deposited and immediately exposed to an ultraviolet lamp to polymerize and thicken and reduce spreading of the composition. Similarly, a thermoset polymer can be deposited and exposed to a heat lamp or other infrared light source.

E. Ink Curing and Processing

After deposition, the metallic ink may be treated to convert the metallic ink to the desired structure and/or material, e.g., an electrical conductor. The treatment can include multiple steps, or can occur in a single step, such as when the metallic ink is rapidly heated and held at the processing temperature for a sufficient amount of time to form an electrical conductor.

A metallic ink that has been applied (e.g., printed) on a substrate may be cured by a number of different methods including, but not limited to thermal, IR, UV, microwave heating and pressure-based curing. By way of non-limiting example, thermal curing can be effected by removing the vehicle (solvents) at low temperatures and creating a reflective print. On some substrates such as paper, no thermal curing step may be necessary, while in others a mild thermal curing step such as, e.g., short exposure to an infra-red lamp may be sufficient. In this particular embodiment, the metallic ink may have a higher absorption cross-section for the IR energy derived from the heat lamp compared to the surrounding substrate and so the applied composition may be preferentially thermally cured.

An optional, initial step may include drying or subliming of the composition by heating or irradiating. In this step, the liquid vehicle (e.g., solvent) is removed from the deposited metallic ink and/or chemical reactions occur in the composition. Non-limiting examples of methods for processing the deposited composition in this manner include methods using a UV, IR, laser or a conventional light source. Heating rates for drying the metallic ink are preferably greater than about 10° C./min., more preferably greater than about 100° C./min. and even more preferably greater than about 1000° C./min. The temperature of the deposited metallic ink can be raised using hot gas or by contact with a heated substrate. This temperature increase may result in further evaporation of vehicle and other species. A laser, such as an IR laser, can also be used for heating. An IR lamp, a hot plate or a belt furnace can also be utilized. It may also be desirable to control the cooling rate of the deposited feature.

The metallic inks of the present invention can be processed for very short times and still provide useful materials. Short heating times can advantageously prevent damage to the underlying substrate. For example, thermal processing times for deposits having a thickness on the order of about 10 μm may be not greater than about 100 milliseconds, e.g., not greater than about 10 milliseconds, or not greater than about 1 millisecond. The short heating times can be provided using laser (pulsed or continuous wave), lamps, or other radiation. Particularly preferred are scanning lasers with controlled dwell times. When processing with belt and box furnaces or lamps, the hold time may often be not longer than about 60 seconds, e.g., not longer than about 30 seconds, or not longer than about 10 seconds. The heating time may even be not greater than about 1 second when processed with these heat sources, and even not greater than about 0.1 second while still providing conductive materials that are useful in a variety of applications. The preferred heating time and temperature will also depend on the nature of the desired feature, e.g., of the desired electronic feature. It will be appreciated that short heating times may not be beneficial if the solvent or other constituents boil rapidly and form porosity or other defects in the feature.

In one aspect of the present invention, the deposited metallic ink may be converted to an electrically electrical conductor at temperatures of not higher than about 300° C., e.g., not higher than about 250° C., not higher than about 225° C., not higher than about 200° C., or even not higher than about 185° C. In many cases it will be possible to achieve substantial conductivity at temperatures of not higher than about 150° C., e.g., at temperatures of not higher than about 125° C., or even at temperatures of not higher than about 100° C. Any suitable method and device and combinations thereof can be used for the conversion, e.g., heating in a furnace or on a hot plate, irradiation with a light source (UV lamp, IR or heat lamp, laser, etc.), combinations of any of these methods, to name just a few.

By way of non-limiting example, after heating to a temperature of about 200° C., or even to a temperature of about 150° C., a deposited composition of the present invention may show a resistivity which is not higher than about 30 times, e.g., not higher than about 20 times, not higher than about 10 times, not higher than about 5 times, or not higher than about 3 times the resistivity of the pure bulk metal or metallic phase (e.g., alloy).

As discussed above, the metallic ink used to form the electrical conductor of the present invention comprises two basic components: particles and a liquid vehicle. The liquid vehicle provides the liquid properties to the ink, enabling it to be printed and dispensed onto the substrate. The nanoparticles preferably have two main components: a metal core and a capping agent in the form of, e.g., a surface layer, coating, or shell. The capping agent preferably stabilizes the particles, inhibiting agglomeration in the liquid phase and providing surface functionality that enables a stable dispersion in the liquid vehicle. After printing, the liquid vehicle is removed (e.g., evaporated) and the capping agent no longer is needed for any of these functions. In fact, the capping agent can now be considered an obstacle for sintering of the metallic particles, inhibiting charge transport. In another preferred aspect of the present invention, the capping agent may be attached to the metallic nanoparticles in a dative manner. When low temperature sintering is performed (e.g., in the range of from about 75° C. to about 250° C., e.g., from about 100° C. to about 150° C.), the capping agent will usually not vaporize or otherwise become volatile and leave the printed feature. Instead, it is assumed that the capping agent moves out of the way, allowing the metallic particles to touch and sinter together, while a substantial amount of the capping agent remains present as part of the printed feature. In a preferred aspect of the present invention, the resulting material comprises a nanocomposite, which comprises a substantially uniform mixture of metal and organic material. Both phases (metal, organic material (capping agent)) may form substantially uniform inclusions with a size in the range of from, e.g., about 5 nm to about 60 nm. In an even more preferred aspect, the metal nanoparticles may be physically necked together to form a percolation network of interconnected metallic nodes. The capping agent of the composite may, for example, fill at least a portion of the pores formed by the interconnected nodes. (See FIG. 4). The capping agent optionally represents not more than about 50% by volume of the nanocomposite, e.g., not more than about 45% by volume, not more than about 40% by volume, not more than about 35% by volume, or not more than about 25% by volume of the total nanocomposite.

In another preferred aspect, the organic material (capping material) may assume a new function: it may promote adhesion of the printed metal structure to a range of organic and polymeric substrates such as, e.g., paper, FR4 or Mylar® (PET) and provide structural strength. As a result of the low-temperature sintering mechanism, a continuous percolation network may be formed that provides continuous channels for the conduction of electrons throughout the printed structure without obstacles.

When high conductivity and a dense, high metal-content material are desired, a higher-temperature sintering may be performed (for example, in the range of from about 300° C. to about 550° C.). During such treatment the capping agent may—at least in part—decompose and/or volatilize. As a result, sintering will occur more rapidly and a much denser metal structure may be formed as compared to a low-temperature structure.

The particles in the metallic ink may optionally be (fully) sintered. The sintering can be carried out using, for example, furnaces, light sources such as heat lamps and/or lasers. In one aspect, the use of a laser advantageously provides very short sintering times and in one aspect the sintering time is not greater than about 1 second, e.g., not greater than about 0.1 seconds, or even not greater than about 0.01 seconds. Laser types include pulsed and continuous wave lasers. In one aspect, the laser pulse length is tailored to provide a depth of heating that is equal to the thickness of the material to be sintered.

After the metallic ink is printed on the substrate, it may be heated to yield the desired electrical performance, adhesion, and abrasion resistance. This heating can be accomplished in a variety of ways such as hot plate, convection oven, infrared radiation, laser radiation, UV exposure, etc. In general, the resistivity of a printed structure will drop with curing temperature and curing time. In one aspect, the detailed time-temperature profile may play a role in the final electrical performance of the printed line or feature: by way of non-limiting example, drying the ink at about 80° C. before heating it to about 120° C. may in some cases result in a feature with a significantly lower conductivity than that of a feature that was printed and immediately heated to about 120° C. without allowing it to dry.

The electrical performance of a cured printed line is often described in terms of the bulk resistivity of the cured line. These values are obtained by measuring the resistance (R) of the printed line, the length (l), and the average cross sectional area (width times thickness: w·d). The bulk resistivity (ρ) is calculated using the equation: ρ (Ωcm)=R(Ω)×w·d/l (cm). The most accurate data are obtained when using the ratiometric resistance measurement procedure which eliminates contact resistance. When adequate sensing probes are used that do not damage the printed metal, in combination with printed contact pads, a two-point probe measurement can also be used to provide reliable data.

In a preferred aspect of the present invention the peak curing temperature and the curing time are the main factors that determine the ultimate electrical performance of the printed metals. In addition, secondary parameters such as heating profile (ramp rate, drying or no drying prior to heating), substrate type (e.g., coated paper, PET, glass, etc.) curing ambient, and heating method (e.g., oven, laser, IR, etc.) may also play a role.

In a preferred aspect of the present invention, high conductivity can be achieved after very short curing times at temperatures above about 200° C. For example, a 60 second cure at 300° C. may yield a printed Ag line with a bulk resistivity value of about 3.8 μΩcm. In another example, high electrical conductivity can be accomplished with curing times in the single digit second range at temperatures of from about 250° C. to about 550° C. Curing processes such as in-line RTP (rapid thermal processing) can be used to cure the printed features after printing and achieve the desired electrical properties. This will enable a significant reduction in tact time in a manufacturing process when compared to competing materials and processes.

The applied composition (e.g., the electrical conductor) may also be cured by irradiation with UV light where the ink contains a photoreactive reagent. The photoreactive reagent may, for example, be a monomer or low molecular weight polymer which polymerizes on exposure to UV light resulting in a robust, insoluble metallic layer. In cases where electronic conductivity is important, a photoreactive metal species may be incorporated into the ink to provide good connectivity between the nanoparticles in the ink after curing. In this particular embodiment, the photoactive metal-containing species is photochemically reduced to form the corresponding metal.

According to a further non-limiting example, the applied (e.g., printed) electrical conductor may be cured by compression. This may be achieved, for example, by exposing the article comprising the applied composition to any of a variety of different processes that “weld” the nanoparticles in the composition (ink). Non-limiting examples of corresponding processes include stamping and roll pressing. In particular, for applications in the security industry (discussed in detail below), subsequent processing steps in the construction of a secure document may include intaglio printing which will result in the exposure of a substrate comprising a deposited metallic feature to high pressure and temperatures in the range of from, e.g., about 50° C. to about 100° C. The temperature or the pressure or both combined should be sufficient to cure the metallic ink and create a reflective and/or electrical conductor.

It will be appreciated by those skilled in the art that any combination of heating, pressing, UV-curing or any other type of radiation curing may be useful in creating desired properties of a (e.g., printed) feature.

It will be appreciated from the foregoing discussion that two or more of the latter process steps (drying, heating and sintering) can be combined into a single process step. Also, one or more of these steps may optionally be carried out in a reducing atmosphere (e.g., in an H₂/N₂ atmosphere for metals that are prone to undergo oxidation, especially at elevated temperature, such as e.g., Ni) or in an oxidizing atmosphere.

The deposited and treated material, e.g., the electrical conductor of the present invention, may be post-treated. The post-treatment can, for example, include cleaning and/or encapsulation of the electrical conductor (e.g., in order to protect the deposited material from oxygen, water or other potentially harmful substances) or other modifications. The same applies to any other metal structures that may be formed (e.g., deposited) with a nanoparticle composition of the present invention.

One exemplary process flow includes the steps of: forming a structure by conventional methods such as lithographic, gravure, flexo, screen printing, photo patterning, thin film or wet subtractive approaches; identifying locations requiring addition of material; adding material by a direct deposition of a low viscosity composition; and processing to form the final product. In a specific aspect, a circuit may be prepared by, for example, screen-printing and then be repaired by localized printing of a low viscosity metallic ink of the present invention.

In another aspect, features larger than approximately 100 μm are first prepared by screen-printing. Features not greater than about 100 μm are then deposited by a direct deposition method using a metallic ink.

Preferably, the electrical conductor of the present invention has a resistivity that is not greater than about 20 times the bulk resistivity of the pure metal/alloy, e.g., not greater than about 10 times the bulk resistivity, not greater than about 5 times the bulk resistivity, or even not greater than about 2 times the bulk resistivity of the pure metal/alloy.

In accordance with the direct-write processes, the present invention comprises the formation of features for devices and components having a small minimum feature size. For example, the method of the present invention can be used to fabricate features having a minimum feature size (the smallest feature dimension in the x-y axis) of not greater than about 200 μm, e.g., not greater than about 150 μm, or not greater than about 100 μm. These feature sizes can be provided using ink-jet printing and other printing approaches that provide droplets or discrete units of composition to a surface. The small feature sizes can advantageously be applied to various components and devices, as is discussed below.

V. Examples

The present invention is further illustrated with reference to an exemplary embodiment thereof wherein silver is the metal of the nanoparticles and polyvinylpyrrolidone is the capping agent.

### A. EXAMPLE 1

### Preparation of Silver Nanoparticles Carrying PVP Thereon

In a mixing tank a solution of 1000 g of PVP (M.W. 10,000, Aldrich) in 2.5 L of ethylene glycol is prepared and heated to 120° C. In a second mixing tank, 125 g of silver nitrate is dissolved in 500 ml of ethylene glycol at 25° C. These two solutions are rapidly combined (within about 5 seconds) in a reactor, in which the combined solutions (immediately after combination at a temperature of about 114° C.) are stirred at 120° C. for about 1 hour. The resultant reaction mixture is allowed to cool to room temperature and about 0.25 L of ethylene glycol is added thereto to replace evaporated ethylene glycol. This mixture is stirred at high speed for about 30 minutes to resuspend any particles that have settled during the reaction. The resultant mixture is transferred to a mixing tank where 12 L of acetone and about 1 L of ethylene glycol are added. The resultant mixture is stirred thoroughly and then transferred to a centrifuge where it is centrifuged for about 20 minutes at 1,500 g to separate the silver nanoparticles from the liquid phase. This affords 70 g of nanoparticles which have PVP adsorbed thereon. The particles are subsequently suspended in 2,000 ml of ethanol and centrifuged to remove, inter alia, excess PVP, i.e., PVP that is not adsorbed on the nanoparticles but is present merely as a contaminant. The resultant filter cake of nanoparticles is dried in a vacuum oven at about 35° C. and about 10⁻² torr to afford dry nanoparticles. These nanoparticles exhibit a PVP content of about 4 to about 8 weight percent, depending on the time the nanoparticles have been in contact with the ethanol. ICP (inductively coupled plasma) data indicates that the longer the particles are in contact with the ethanol, the more of the acetone and ethylene glycol present in the PVP matrix is displaced by ethanol, resulting in particles with an increasingly higher silver content.

### B. EXAMPLE 2

### Preparation and Testing of Composition for Ink-Jet Printing

Silver nanoparticles prepared according to the process described in Example 1 (ranging from about 30 nm to about 50 nm in size) are suspended in a solvent mixture composed of, in weight percent based on the total weight of the solvent mixture, 40% of ethylene glycol, 35% of ethanol and 25% of glycerol to produce an ink for ink-jet printing. The concentration of the silver particles in the ink is 20% by weight. The ink is chemically stable for 6 months, some sedimentation occurring after 7 days at room temperature.

The ink had the following properties:

| | | |
|---|---|---|
| Viscosity* (22° C.) | 14.4 | cP |
| Surface tension** (25° C.) | 31 | dynes/cm |
| Density | 1.24 | g/cc |

*measured at 100 rpm with a Brookfield DVII+ viscometer (spindle no. 18).
**measured with a KSV Sigma 703 digital tensiometer with a standard Du Nouy ring method.

1. Printing and Properties of Printed Features

A Spectra SE 128 head (a commercial piezo ink-jet head) is loaded with the ink of Example 2 and the following optimized printing parameters are established:

Optimized Jetting Parameters (at 22-23° C.):

| | |
|---|---|
| Pulse Voltage | 120 Volts |
| Pulse Frequency | 500 Hz (for up to one 1 hour of continuous |
| | operation) |
| Pulse Rise Time | 2.5 μs |
| Pulse Width | 12.0 μs |
| Pulse Fall Time | 2.5 μs |
| Meniscus Vacuum | 3.0 inches of water |

Performance Summary:

| | |
|---|---|
| Drop Size | 39 μm (calculated volume 31 pL) |
| Drop Velocity | 0.33 m/s |
| Spot Size (average) | 70 μm (on Kapton ®; measured |
| | using optical microscope) |

The deposited ink can be rendered conductive after curing in air at temperatures as low as 100° C. The ink exhibits a high metal yield, allowing single pass printing.

Using the above optimized jetting parameters, the ink of Example 2 is deposited in a single pass with a Spectra SE 128 head on a Kapton® substrate and on a glass substrate to print a line. The line has a maximum width of about 140 μm (Kapton®) and about 160 μm (glass) and a parabolic cross-section. The thickness of the line at the edges averages about 275 nm (Kapton®) and about 240 nm (glass) and the maximum height of the line is about 390 nm (Kapton® and glass). The differences between Kapton® and glass reflect the different wetting behavior of the ink on these two types of substrate materials.

Single pass printing with the ink of Example 2 affords a sheet resistivity of from about 0.1 to about 0.5 Ω/m². The printed material shows a bulk resistivity in the fully sintered state of from about 4 to about 5 μΩcm (about 2.5-3 times the bulk resistivity of silver).

The polymer (polyvinylpyrrolidone (PVP)) on the surface of the silver nanoparticles allows the sintering of a deposited ink at very low temperatures, e.g., in the range of from about 100° C. to about 150° C. The PVP does not volatilize or significantly decompose at these low temperatures. Without being bound by a particular theory, it is believed that at these low temperatures the polymer moves out of the way, allowing the cores of the nanoparticles to come into direct contact and sinter together (necking). In comparison to its anti-agglomeration effect in the printing ink prior to printing, the polymer in the deposited and heat-treated ink assumes a new function, i.e., it promotes the adhesion of the printed material to a range of polymeric substrates such as, e.g., FR4 (fiberglass-epoxy resin) and Mylar® (polyethylene terephthalate) and provides structural strength. As a result of the low-temperature sintering mechanism a continuous percolation network is formed that provides continuous channels for the conduction of electrons throughout the material without obstacles.

When higher-temperature sintering is performed (at about 300° C. to about 550° C.), the polymer volatilizes. As a result, sintering will occur and, in comparison to low-temperature sintering, a much denser metal material is formed. This leads to a better conductivity (close to the conductivity of the bulk metal), better adhesion to substrates such as glass, and better structural integrity and/or scratch resistance.

In the low temperature sintering range (from about 100° C. to about 150° C.), described above, the present ink can advantageously be employed for applications such as, e.g., printed RF ID antennas and tags, digitally printed circuit boards, smart packages, “disposable electronics” printed on plastics or paper stock, etc. In the medium temperature range (from about 150° C. to about 300° C.) the ink may, for example, be used for printing interconnects for applications in printed logic and printed active matrix backplanes for applications such as polymer electronics, OLED displays, AMLCD technology, etc. In the high temperature range (from about 300° C. to about 550° C.) its good performance and adhesion to glass make it useful for printed display applications such as, e.g., plasma display panels.

2. Electric Performance

After the ink is printed on the substrate, it needs to be treated thermally and/or by irradiation to yield the desired electrical performance, adhesion and abrasion resistance. This treatment can be accomplished in a variety of ways such as hot plate, convection oven, infrared radiation, laser radiation, UV exposure, etc.

As a general rule, the resistivity of a printed feature will drop with curing temperature and curing time. The detailed time-temperature profile may also play a role. For example, drying the ink at a temperature of not higher than about 80° C., e.g., not higher than about 70° C., or not higher than about 60° C. before heating it to a temperature of at least about 100° C., e.g., at least about 110° C., or at least about 120° C. may result in a feature with lower conductivity than that of a line that was immediately heated to a temperature of at least about 100° C., e.g., at least about 110° C., or at least about 120° C. without allowing it to dry first.

The peak curing temperature and the curing time are main factors that determine the ultimate performance of a feature made from an ink of the present invention. In addition, secondary parameters such as heating profile (ramp rate, drying prior to curing), substrate type (coated paper, PET, glass etc.), curing ambient and heating method (oven, laser, IR etc.) may also play a role.

In one experiment, a line was printed on a Kapton® substrate using the ink of Example 2 under ambient conditions and then immediately transferred to an oven at a predetermined temperature without drying the ink. At oven temperatures above about 200° C. high conductivity could be achieved after very short curing times. For example, a 60 second cure at an oven temperature of 300° C. yielded a printed silver line exhibiting a bulk resistivity of 3.8 μΩcm. After 60 seconds at 250° C. and after about 15 minutes at 200° C. the resistivity was about 10 μΩcm. After about 60 minutes at 150° C. a resistivity of about 13 μΩcm was obtained and remained substantially constant thereafter. From an extrapolation of the obtained data it is expected that in the temperature range from about 350° C. to about 400° C. a full curing can be accomplished in less than 10 seconds, which will enable curing processes such as in-line RTP (rapid thermal processing), and the associated reduction in tact time in a manufacturing process.

In this regard, it is to be noted that using the bulk resistivity value of a printed silver conductor and comparing it to the bulk resistivity of a fully dense silver object of the same geometry (length, width and layer thickness) does not usually provide a reliable indication of the actual conductivity of the printed metal. This applies particularly to low curing temperatures (e.g., below about 150° C.). In these cases, the final deposit has a significant amount of residual porosity and contains a significant amount of polymer. For example, the actual metal content may be less than 50 weight percent. Conductivity in these materials is accomplished through necking of the Ag particles which results in an efficient percolation network. It is therefore more straightforward to compare the sheet resistivities (expressed as Ω/m²) of a printed feature and a fully dense feature that has the same silver content per unit area as the printed feature.

3. Adhesion to the Substrate

The silver nanoparticles of the composition of Example 2 carry polymer (PVP) on the surfaces thereof. This polymer may provide improved structural integrity of a printed feature on a variety of substrates when curing is carried out at relatively low temperatures (e.g., at temperatures of from about 100° C. to about 250° C.). As set forth above, since at these temperatures the polymer will not volatilize/decompose, it is believed that the polymer merely rearranges to allow the metal cores of the particles to come into contact with each other and sinter together. In this case, the polymer can serve as adhesion promoter between the silver particles and the substrate. In addition, the polymer may provide additional cohesive strength between individual particles.

A stringent adhesion test according to ASTM D3359-02 was performed to evaluate the adhesion performance of the silver ink on a variety of substrates as a function of the curing temperature. In this test, adhesion is rated on a scale from 0 (poor) to 5 (good) based on the percentage of flaking from a cross-cut area. Using a sharp blade, horizontal and vertical lines are made with 1 mm spacing. Scotch adhesive tape is applied under pressure and peeled off under an angle of 180°. The results obtained were as follows:

On an FR4 substrate the adhesion was rated almost 4 in the curing temperature range of from 100° C. to 175° C.

On a Mylar® substrate the adhesion was between about 2 and 3.5 in the curing temperature range of from 100° C. to 175° C. On a Kapton® substrate the adhesion was about 1.5 at curing temperatures of 200° C. and 250° C. On an ITO substrate the adhesion was between about 1.5 and about 4.5 in the curing temperature range of from 350° C. to 550° C. On a glass substrate the adhesion was between about 1 and about 2 in the curing temperature range of from 350° C. to 550° C. An addition to the ink of bismuth nitrate in a weight ratio of Ag:Bi of about 12:1 afforded an adhesion rating on glass between about 3 and about 4 in the temperature range of from 100° C. to 550° C.

### C. EXAMPLE 3

### Conductivity Testing of Compositions on Various Paper Substrates

It was found that the Ag ink composition of Example 2 yields ink-jet printed lines on Epson Gloss IJ ink-jet paper that exhibit an electric resistance after annealing at 100° C. which is comparable to that of the same ink printed on Kapton and annealed at 200° C.

In one set of tests, the following experiments were carried out:

An aqueous silver ink was jetted onto glossy IJ photo paper (Canon), producing three groups of 4 lines; 1 set as single pass, 1 set as double pass, and 1 set as triple pass. All three sets were annealed on a hot plate set to 200° C. for 30 minutes. After the annealing, the lines were tested for electrical conductivity; all lines failed to exhibit conductivity.

The solvent-based Ag ink of Example 2 was printed on EPSON S041286 Gloss photo paper to produce samples for comparison testing with a commercially available Ag ink sample (Nippon Paint) printed on Canon gloss paper (model not known). Two samples were printed, 1 coupon with a single print pass and 1 coupon with a double print pass.

The double pass print was annealed at 100° C. for 60 minutes.

The commercial Ag ink sample was cured at 100° C. for 60 minutes.

The single pass print was annealed at 100° C. for 110 minutes.

Both samples produced with the ink of Example 2 exhibited very good conductivity, comparable to the same silver ink, printed on Kapton, and annealed at 200° C. for 30 minutes. The commercially available ink yielded a conductivity much worse than that of the ink samples according to the present invention.

The ink of Example 2 was printed on four different substrates: (a) Kapton HN-300, (b) Hammermill 05502-0 gloss color copy paper, (c) Canon Bubblejet Gloss Photo Paper GP-301 and (d) Epson Gloss Photo Paper for ink-jet S041286.

The results listed in Table 4, below, confirm the superior performance of the Example 2 ink/Epson paper combination.

TABLE 4
PERFORMANCE OF EXAMPLE 2 METALLIC INKS
ON CERTAIN EPSON SUBSTRATES

| | | Cure | Approx. Resistivity |
|---|---|---|---|
| Ink | Substrate | Temp/Time | (μΩ *cm)¹ |
| Example 2 | Kapton | 200° C./30 min | 21 |
| Example 2 | Kapton | 100° C./60 min | 180 |
| Example 2 | Epson Photo Paper | 100° C./60 min | 16 |
| Example 2 | Xerox High Gloss | 100° C./60 min | No Conductivity |
| Example 2 | Canon Photo Paper | 100° C./60 min | 525 |
| Commercial | Canon Photo Paper | 100° C./60 min | 5400² |

¹assuming 1-micron line thickness.
²average based on fewer measurements than ink of Example 2.

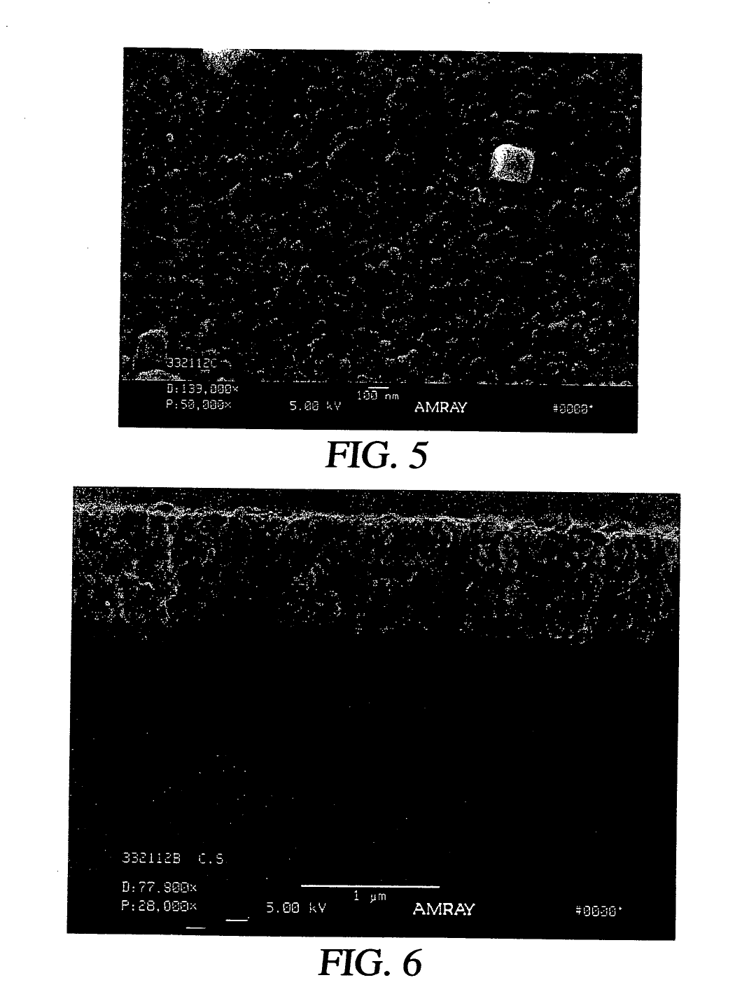

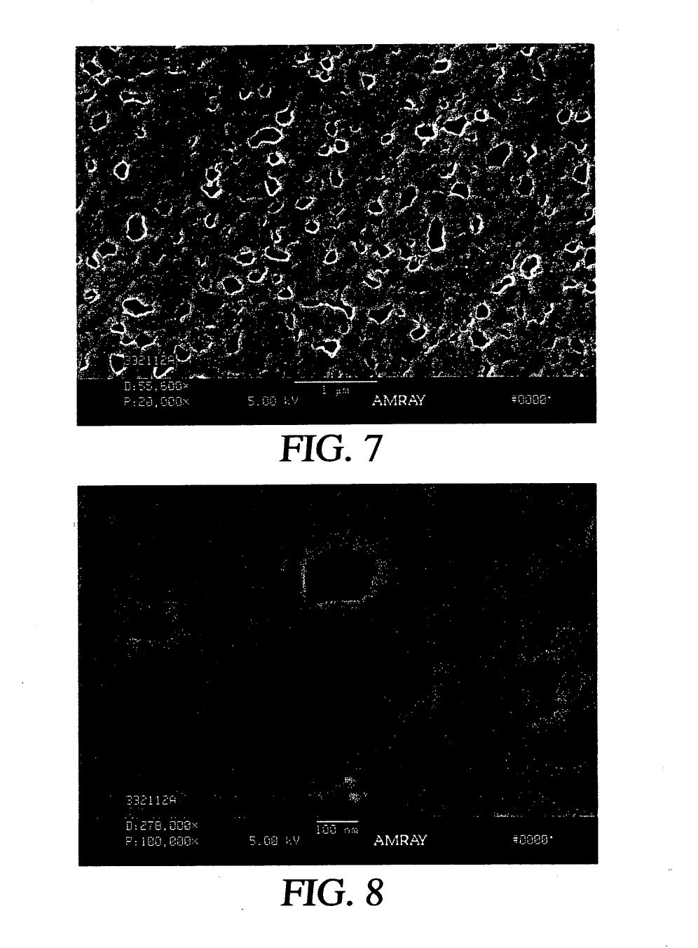

FIGS. 5-8 present Scanning Electron Micrographs (SEMs) of the conductive feature formed from the ink of Example 2 (20% silver-containing ink) printed on Epson Photo Paper, cured at 100° C. for 60 minutes. The porous nanostructure of the conductive features is clearly evident in FIGS. 7 & 8.

### D. EXAMPLE 4

### Aqueous Ink Formulation

An ink-jet printable ink is prepared by combining 16 parts by weight of silver nanoparticles similar to those prepared in Example 1, 42 parts by weight of ethylene glycol and 42 parts by weight of water. The ink shows the following properties:

| | | |
|---|---|---|
| Viscosity (25° C.) | 3.9 | cPs |
| Surface Tension (20° C.) | 58.3 | dynes/cm |
| Density (RT) | 1.2 | g/cm³ |

It is noted that the foregoing examples have been provided merely for the purpose of explanation and are in no way to be construed as limiting of the present invention. While the present invention has been described with reference to an exemplary embodiment, it is understood that the words that have been used are words of description and illustration, rather than words of limitation. Changes may be made, within the purview of the appended claims, as presently stated and as amended, without departing from the scope and spirit of the present invention in its aspects. Although the invention has been described herein with reference to particular means, materials and embodiments, the invention is not intended to be limited to the particulars disclosed herein. Instead, the invention extends to all functionally equivalent structures, methods and uses, such as are within the scope of the appended claims.

We claim:

1. An electrical conductor, comprising a network of interconnected metallic nodes, the nodes comprising a metallic composition, the network defining a plurality of pores having an average pore volume of less than about 10,000,000 nm³, and the electrical conductor having a resistivity of not greater than about 10× the resistivity of the bulk metallic composition.

2. The electrical conductor of claim 1, wherein the network comprises fused interconnected metallic nodes.

3. The electrical conductor of claim 2, wherein the metallic composition comprises a metal selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead.

4. The electrical conductor of claim 2, wherein the metallic composition comprises an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead.

5. The electrical conductor of claim 4, wherein the alloy comprises a combination of metals selected from the group consisting of silver/nickel, silver/copper, silver/cobalt, platinum/copper, platinum/ruthenium, platinum/iridium, platinum/gold, palladium/gold, palladium/silver, nickel/copper, nickel/chromium, and titanium/palladium/gold.

6. The electrical conductor of claim 4, wherein the alloy comprises at least three metals.

7. The electrical conductor of claim 2, wherein the resistivity is not greater than 5× the resistivity of the metallic composition.

8. The electrical conductor of claim 2, wherein at least a portion of the pores are at least partially filled with a composition selected from the group consisting of carbon, alumina, silica, and glass.

9. The electrical conductor of claim 2, wherein at least a portion of the pores are at least partially filled with an organic material.

10. The electrical conductor of claim 9, wherein the organic material comprises an organic polymer.

11. The electrical conductor of claim 10, wherein the polymer comprises units of a monomer, which comprises at least one heteroatom selected from O and N.

12. The electrical conductor of claim 10, wherein the polymer comprises units of a monomer which comprises one or more of a hydroxyl group, a carbonyl group, an ether group, an amido group, a carboxyl group, an imido group and an amino group.

13. The electrical conductor of claim 10, wherein the polymer comprises units of at least one monomer which comprises a structural element selected from —COO—, —O—CO—O—, —C—O—C—, —CO—O—CO—, —CONR—, —NR—CO—O—, —NR¹—CO—NR²—, —CO—NR—CO—, —SO₂—NR— and —SO₂—O—, wherein R, R¹ and R² independently represent hydrogen or an organic radical.

14. The electrical conductor of claim 10, wherein the polymer comprises a polymer of vinylpyrrolidone.

15. The electrical conductor of claim 14, wherein the polymer of vinylpyrrolidone comprises a homopolymer.

16. The electrical conductor of claim 14, wherein the polymer of vinylpyrrolidone comprises a copolymer.

17. The electrical conductor of claim 16, wherein the copolymer is selected from the group consisting of a copolymer of vinylpyrrolidone and vinylacetate; a copolymer of vinylpyrrolidone and vinylimidazole; a copolymer of vinylpyrrolidone and styrene; a copolymer of vinylpyrrolidone and 2-dimethylaminoethyl methacrylate; and a copolymer of vinylpyrrolidone and vinylcaprolactam.

18. The electrical conductor of claim 2, wherein the average pore volume is less than about 1,000,000 nm³.

19. The electrical conductor of claim 18, wherein the average pore volume is less than about 100,000 nm³.

20. The electrical conductor of claim 2, wherein the average distance between adjacent pores is from about 1 nm to about 500 nm.

21. The electrical conductor of claim 2, wherein the electrical conductor comprises the pores in an amount less than about 50 volume percent, based on the total volume of the electrical conductor.

22. The electrical conductor of claim 21, wherein the pores comprise less than about 25 volume percent of the electrical conductor, based on the total volume of the electrical conductor.

23. The electrical conductor of claim 2, wherein the pores have an ordered arrangement within the electrical conductor.

24. The electrical conductor of claim 2, wherein the pores have a random arrangement within the electrical conductor.

25. The electrical conductor of claim 2, formed by a process comprising the steps of:
(a) providing an ink comprising metallic nanoparticles and a liquid vehicle;
(b) depositing the ink on a substrate; and
(c) removing a majority of the liquid vehicle from the deposited ink to form the nodes and the pores in the electrical conductor.

26. The electrical conductor of claim 25, wherein step (c) comprises:
heating the deposited ink under conditions effective to remove the majority of the liquid vehicle, and sinter adjacent metallic nanoparticles to one another to form the nodes and the pores of the electrical conductor.

27. The electrical conductor of claim 26, wherein step (c) comprises heating the ink on the substrate to a maximum temperature of less than about 200° C.

28. The electrical conductor of claim 26, wherein the maximum temperature is less than about 100° C.

29. The electrical conductor of claim 26, wherein the ink further comprises a composition selected from the group consisting of alumina, silica, glass, and carbon, the composition filling at least a portion of the pores in step (c).

30. The electrical conductor of claim 26, wherein the ink further comprises an organic material, which fills at least a portion of the pores in step (c).

31. The electrical conductor of claim 30, wherein the organic material comprises a composition selected from the group consisting of remaining ink solvents, carbon and an organic polymer.

32. The electrical conductor of claim 31, wherein the polymer comprises units of a monomer, which comprises at least one heteroatom selected from O and N.

33. The electrical conductor of claim 31, wherein the polymer comprises units of a monomer which comprises one or more of a hydroxyl group, a carbonyl group, an ether group, an amido group, a carboxyl group, an imido group and an amino group.

34. The electrical conductor of claim 31, wherein the polymer comprises units of at least one monomer which comprises a structural element selected from —COO—, —O—CO—O—, —C—O—C—, —CO—O—CO—, —CONR—, —NR—CO—O—, —NR¹—CO—NR²—, —CO—NR—CO—, —SO₂—NR— and —SO₂—O—, wherein R, R¹ and R² independently represent hydrogen or an organic radical.

35. The electrical conductor of claim 31, wherein the polymer comprises a polymer of vinyl pyrrolidone.

36. The electrical conductor of claim 35, wherein the polymer of vinyl pyrrolidone comprises a homopolymer.

37. An electrical conductor, comprising a plurality of touching metallic nanoparticles, wherein the nanoparticles are tightly packed and form a plurality of voids, wherein at least about 95 percent of the nanoparticles, by number, are not sintered to any adjacent nanoparticles, the electrical conductor having a resistivity of not greater than about 20× the resistivity of the bulk metallic composition.

38. The electrical conductor of claim 37, wherein the metallic nanoparticles comprise a metal selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead.

39. The electrical conductor of claim 37, wherein the metallic nanoparticles comprise an alloy comprising at least two metals, each of the two metals being selected from the group consisting of silver, gold, copper, nickel, cobalt, palladium, platinum, indium, tin, zinc, titanium, chromium, tantalum, tungsten, iron, rhodium, iridium, ruthenium, osmium, aluminum and lead.

40. The electrical conductor of claim 39, wherein the alloy comprises a combination of metals selected from the group consisting of silver/nickel, silver/copper, silver/cobalt, platinum/copper, platinum/ruthenium, platinum/iridium, platinum/gold, palladium/gold, palladium/silver, nickel/copper, nickel/chromium, and titanium/palladium/gold.

41. The electrical conductor of claim 39, wherein the alloy comprises at least three metals.

42. The electrical conductor of claim 37, wherein the resistivity is not greater than 10× the resistivity of the metallic composition.

43. The electrical conductor of claim 42, wherein the resistivity is not greater than 5× the resistivity of the metallic composition.

44. The electrical conductor of claim 37, wherein at least a portion of the voids are at least partially filled with a composition selected from the group consisting of carbon, alumina, silica, and glass.

45. The electrical conductor of claim 37, wherein at least a portion of the voids are at least partially filled with an organic material.

46. The electrical conductor of claim 45, wherein the organic material fills at least 70 volume percent of the voids.

47. The electrical conductor of claim 46, wherein the organic material fills at least 90 volume percent of the voids.

48. The electrical conductor of claim 47, wherein the organic material fills at least 95 volume percent of the voids.

49. The electrical conductor of claim 45, wherein the organic material comprises an organic polymer.

50. The electrical conductor of claim 45, wherein the polymer comprises units of a monomer, which comprises at least one heteroatom selected from O and N.

51. The electrical conductor of claim 45, wherein the polymer comprises units of a monomer which comprises one or more of a hydroxyl group, a carbonyl group, an ether group, an amido group, a carboxyl group, an imido group and an amino group.

52. The electrical conductor of claim 45, wherein the polymer comprises units of at least one monomer which comprises a structural element selected from —COO—, —O—CO—O—, —C—O—C—, —CO—O—CO—, —CONR—, —NR—CO—O—, —NR¹—CO—NR²—, —CO—NR—CO—, —SO₂—NR— and —SO₂—O—, wherein R, R¹ and R² independently represent hydrogen or an organic radical.

53. The electrical conductor of claim 45, wherein the polymer comprises a polymer of vinylpyrrolidone.

54. The electrical conductor of claim 53, wherein the polymer of vinylpyrrolidone comprises a homopolymer.

55. The electrical conductor of claim 53, wherein the polymer of vinylpyrrolidone comprises a copolymer.

56. The electrical conductor of claim 55, wherein the copolymer is selected from the group consisting of a copolymer of vinylpyrrolidone and vinylacetate; a copolymer of vinylpyrrolidone and vinylimidazole; a copolymer of vinylpyrrolidone and styrene; a copolymer of vinylpyrrolidone and 2-dimethylaminoethyl methacrylate; and a copolymer of vinylpyrrolidone and vinylcaprolactam.

57. The electrical conductor of claim 37, wherein the plurality of voids has an average void volume of less than about 10,000,000 nm³.

58. The electrical conductor of claim 57, wherein the average void volume is less than about 1,000,000 nm³.

59. The electrical conductor of claim 58, wherein the average void volume is less than about 100,000 nm³.
